(19) United States
(12) Patent Application Publication
(10) Pub. No.: US 2023/0335575 A1
(43) Pub. Date: Oct. 19, 2023

(54) DISPLAY DEVICE AND METHOD OF FABRICATING THE SAME

(71) Applicant: Samsung Display Co., LTD., Yongin-si (KR)

(72) Inventors: Jin Woo LEE, Yongin-si (KR); Cheon Jae MAENG, Yongin-si (KR); Zu Seok OH, Yongin-si (KR); Jae Hyoung YOUN, Yongin-si (KR); Jeong Hyun LEE, Yongin-si (KR); Seung Jin CHU, Yongin-si (KR)

(73) Assignee: Samsung Display Co., LTD., Yongin-si (KR)

(21) Appl. No.: 17/975,712

(22) Filed: Oct. 28, 2022

(30) Foreign Application Priority Data
Apr. 13, 2022 (KR) 10-2022-0045944

(51) Int. Cl. H01L 27/15; H01L 33/24; H01L 33/44; H01L 33/50

(52) U.S. Cl. CPC H01L 27/156; H01L 33/24; H01L 33/44; H01L 33/50; H01L 2933/0041

(57) ABSTRACT

A display device including a display area and a non-display area includes: a light emitting element on a base layer in the display area; a dam member on the base layer in the non-display area; a color filter layer disposed in the display area and the non-display area and including an outer color filter layer disposed in the non-display area; and a cover layer on the color filter layer. The cover layer may cover at least a portion of the outer color filter layer.

### CROSS-REFERENCE TO RELATED APPLICATION(S)

The application claims priority to and benefits of Korean Patent Application No. 10-2022-0045944 under 35 U.S.C. § 119, filed on Apr. 13, 2022, in the Korean Intellectual Property Office (KIPO), the entire contents of which are incorporated herein by reference.

### BACKGROUND

### 1. Technical Field

Various embodiments relate to a display device and a method of fabricating the display device.

### 2. Description of Related Art

Recently, as interest in information display increases, research and development on display devices have been continuously conducted.

### SUMMARY

Embodiments provide a display device capable of being protected from an external influence, and a method of fabricating the display device.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device including a display area and a non-display area may include: a light emitting element on a base layer in the display area; a dam member on the base layer in the non-display area; a color filter layer disposed in the display area and the non-display area, the color filter layer including an outer color filter layer disposed in the non-display area; and a cover layer on the color filter layer. The cover layer may cover at least a portion of the outer color filter layer.

In an embodiment, the display device may further include a passivation layer on the base layer, and including a first passivation layer in the display area, and a second passivation layer in the non-display area; a bank on the first passivation layer; and a color conversion layer in an area surrounded by the bank. The dam member may be on the second passivation layer. At least a portion of the dam member and the bank may include a same material.

In an embodiment, the display device may further include a capping layer. At least a portion of the capping layer may encapsulate the color conversion layer. The capping layer may cover a side surface of the dam member facing an outer portion of the display device.

In an embodiment, a height of the dam member and a height of the bank may be substantially same as each other.

In an embodiment, the passivation layer includes an organic material. The capping layer may cover a side surface of the second passivation layer facing the outer portion of the display device.

In an embodiment, the display device may further include: a capping layer encapsulating the color conversion layer; and an interlayer insulating layer disposed between the passivation layer and the base layer. The first passivation layer and the second passivation layer may be spaced apart from each other. The capping layer and the interlayer insulating layer may contact each other in an area where the first passivation layer and the second passivation layer are spaced apart from each other.

In an embodiment, the cover layer may cover an outer surface of the outer color filter layer facing an outer portion of the display device.

In an embodiment, the outer color filter layer may include a first outer color filter layer and a second outer color filter layer. The first outer color filter layer and the second outer color filter layer may be spaced apart from each other on an upper surface of the dam member.

In an embodiment, the display device may further include a capping layer at least a portion of which is disposed on the dam member. The first outer color filter layer and the second outer color filter layer may be separated from each other to form an opening area overlapping the dam member in a plan view. The cover layer and the capping layer may contact each other in the opening area.

In an embodiment, the outer color filter layer may extend along a side of the dam member.

In an embodiment, the base layer including a substrate may be formed on a surface of the display device, and an outer film layer including a film member may be formed on another surface of the display device.

In an embodiment, the light emitting element may include an organic light emitting diode including an organic material or a subminiature light emitting diode including an inorganic material.

In an embodiment, a display device including a display area and a non-display area may include: a light emitting element on a base layer in the display area; a dam member on the base layer in the non-display area; and a color filter layer disposed in the display area and the non-display area, the color filter layer including an outer color filter layer disposed in the non-display area. The color filter layer may include an outer color filter layer in the non-display area. The outer color filter layer may include a first outer color filter layer and a second outer color filter layer that are spaced apart from each other on an upper surface of the dam member.

In an embodiment, a method of fabricating a display device may include: disposing a pixel circuit layer and a light emitting element on a base layer of a mother substrate; forming a dam member on the base layer; forming a color filter layer on the base layer, the forming of the color filter layer including: forming at least a portion of the color filter layer to overlap an area in which the light emitting element is disposed, and forming an outer color filter layer on a first side surface of the dam member; and disposing a cover layer on the color filter layer. The cover layer may cover at least a portion of the outer color filter layer.

In an embodiment, the method may further include cutting the mother substrate along a scribing line to form a plurality of display panels. The disposing of the pixel circuit layer may include disposing a passivation layer on the base layer. The scribing line and the passivation layer may not overlap each other.

In an embodiment, the method may further include disposing alignment electrodes on the base layer. The disposing of the light emitting element may include: supplying ink including the light emitting element and a solvent onto the base layer; generating an electric field by providing electrical signals to the alignment electrodes; and aligning the light emitting element based on the electric field.

In an embodiment, the cover layer may cover an outer surface of the outer color filter layer facing an outer portion of the display device.

In an embodiment, the cover layer covers an outer surface of the outer color filter layer facing an outer portion of the display device.

In an embodiment, the forming of the outer color filter layer may include: forming a first outer color filter layer for covering the first side surface of the dam member; and forming a second outer color filter layer for covering a second side surface of the dam member. The first outer color filter layer and the second outer color filter layer may be spaced apart from each other on an upper surface of the dam member.

In an embodiment, the cover layer may contact a capping layer disposed on a surface of the dam member in an area by which the first outer color filter layer and the second outer color filter layer are spaced apart from each other.

### BRIEF DESCRIPTION OF THE DRAWINGS

FIG. 1 is a schematic perspective view illustrating a light emitting element in accordance with an embodiment.

FIG. 2 is a schematic sectional view illustrating the light emitting element in accordance with an embodiment.

FIG. 3 is a schematic plan view illustrating a display device in accordance with an embodiment.

FIG. 4 is a schematic plan view illustrating a sub-pixel in accordance with an embodiment.

FIG. 5 is a schematic sectional view illustrating the sub-pixel in accordance with an embodiment.

FIG. 6 is a schematic sectional view illustrating a pixel in accordance with an embodiment.

FIG. 7 is a schematic sectional view illustrating the sub-pixel in accordance with an embodiment.

FIG. 8 is a schematic sectional view illustrating the display device in accordance with an embodiment.

FIGS. 9 to 18 are schematic views illustrating, by process steps, a method of fabricating the display device in accordance with an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Various embodiments of the disclosure relate to a display device and a method of fabricating the display device. Hereinafter, a display device and a method of fabricating the display device in accordance with an embodiment will be described with reference to the attached drawings.

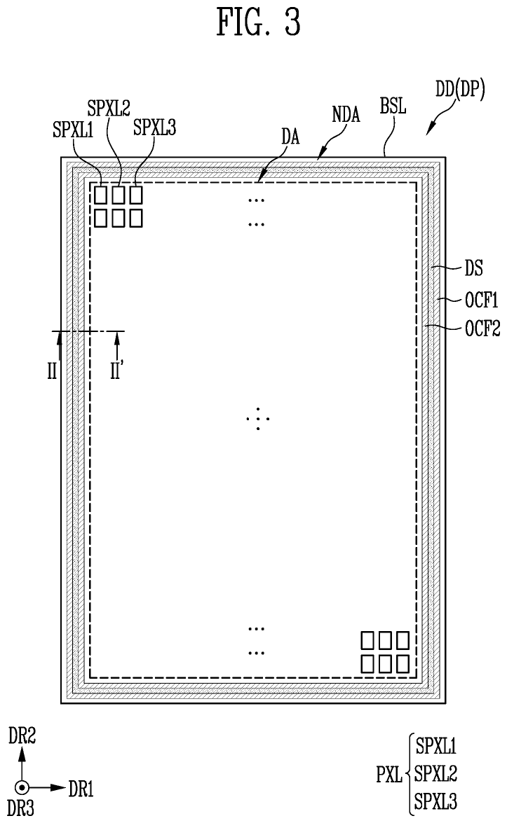

A display device DD (refer to FIG. 3) in accordance with an embodiment may include a light emitting element LD that emits light. In an embodiment, the light emitting element LD may be a self-emissive element, and be formed of an organic light emitting diode (OLED). In another example, the light emitting element LD may be a subminiature light emitting diode including an inorganic material. The type of light emitting element LD is not limited to a specific example. Hereinafter, for convenience of description, the following description will be made based on an embodiment in which the light emitting element LD is a substantially subminiature light emitting diode including an inorganic material.

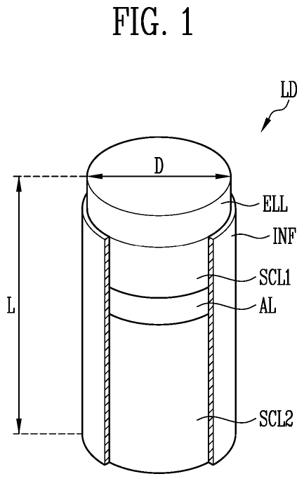

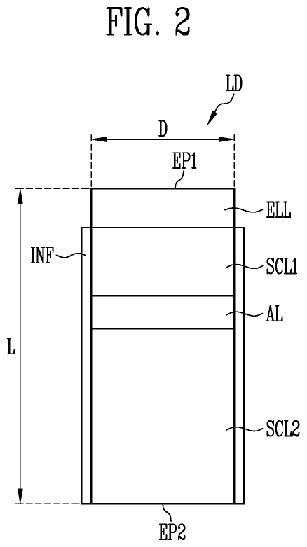

The light emitting element LD in accordance with an embodiment will be described with reference to FIGS. 1 and 2. FIG. 1 is a schematic perspective view illustrating a light emitting element in accordance with an embodiment. FIG. 2 is a schematic sectional view illustrating the light emitting element in accordance with an embodiment.

In accordance with an embodiment, the light emitting element LD may be formed to emit light. For example, the light emitting element LD may be a light emitting diode including an inorganic material.

The light emitting element LD may have various shapes. For example, the light emitting element LD may have a shape extending in a direction. In an embodiment, FIGS. 1 and 2 illustrate a pillar-like light emitting element LD. However, the type and shape of the light emitting element LD is not limited thereto.

The light emitting element LD may include a first semiconductor layer SCL1, a second semiconductor layer SCL2, and an active layer AL disposed between the first and second semiconductor layers SCL1 and SCL2. For example, in case that a direction, in which the light emitting element LD extends, refers to a longitudinal direction, the light emitting element LD may include the first semiconductor layer SCL1, the active layer AL, and the second semiconductor layer SCL2 which are successively stacked in the longitudinal direction. The light emitting element LD may further include an electrode layer ELL and an element insulating layer INF.

The light emitting element LD may be formed in a pillar-like shape extending in a direction (e.g., the longitudinal direction). The light emitting element LD may include a first end portion EP1 and a second end portion EP2. The first semiconductor layer SCL1 may be adjacent to the first end portion EP1 of the light emitting element LD. The second semiconductor layer SCL2 may be adjacent to the second end portion EP2. The electrode layer ELL may be adjacent to the first end portion EP1.

The light emitting element LD may be a light emitting element fabricated in a pillar-like shape by an etching process. For example, the term “pillar-like shape” may include a rod-like shape and a bar-like shape such as a cylindrical shape and a prismatic shape that is longer in a longitudinal direction (i.e., to have an aspect ratio greater than 1), and the cross-sectional shape thereof is not limited to a specific shape. For example, the length L of the light emitting element LD may be greater than the diameter D thereof (or a width of the cross-section thereof).

The light emitting element LD may have a size ranging from the nanometer scale to the micrometer scale. For example, the light emitting element LD may have a diameter D (or a width) and/or a length L ranging from the nanometer scale to the micrometer scale. However, the size of light emitting element LD is not limited thereto.

The first semiconductor layer SCL1 may be a first conductive semiconductor layer. The first semiconductor layer SCL1 may be disposed on the active layer AL and include a semiconductor layer having a type different from that of the second semiconductor layer SCL2. For example, the first semiconductor layer SCL1 may include a P-type semiconductor layer. For instance, the first semiconductor layer SCL1 may include a P-type semiconductor layer which includes any one semiconductor material of InAlGaN, GaN, AlGaN, InGaN, AlN, and InN, and is doped with a first conductive dopant such as Mg. However, the material for forming the first semiconductor layer SCL1 is not limited thereto, and the first semiconductor layer SCL1 may be formed of various other materials.

The active layer AL may be disposed between the first semiconductor layer SCL1 and the second semiconductor layer SCL2, and have a single-quantum well structure or a multi-quantum well structure. The position of the active layer AL may be changed in various ways according to the type of the light emitting element LD, rather than being limited to a specific example.

A cladding layer doped with a conductive dopant may be formed over and/or under the active layer AL. For example, the cladding layer may be formed of an AlGaN layer or an InAlGaN layer. In an embodiment, a material such as AlGaN or InAlGaN may be used to form the active layer AL, and various other materials may be used to form the active layer AL.

The second semiconductor layer SCL2 may be a second conductive semiconductor layer. The second semiconductor layer SCL2 may be disposed on the active layer AL and include a semiconductor layer of a type different from that of the first semiconductor layer SCL1. For example, the second semiconductor layer SCL2 may include an N-type semiconductor layer. For instance, the second semiconductor layer SCL2 may include any one semiconductor material of InAlGaN, GaN, AlGaN, InGaN, AlN, and InN, and may include an N-type semiconductor layer doped with a second conductive dopant such as Si, Ge, or Sn. However, the material for forming the second semiconductor layer SCL2 is not limited thereto, and the second semiconductor layer SCL2 may be formed of various other materials.

In case that a voltage equal to or greater than a threshold voltage is applied between the opposite end portions of the light emitting element LD, the light emitting element LD may emit light by coupling (or recombination) of electron-hole pairs in the active layer AL. For example, the light emitting element LD may be used as a light source of various light emitting devices as well as a pixel of the display device.

The element insulating layer INF may be disposed on a surface of the light emitting element LD. The element insulating layer INF may be formed on the surface of the light emitting element LD to enclose (or surround) an outer circumferential surface of at least the active layer AL, and may further enclose (or surround) the first and second semiconductor layers SCL1 and SCL2. The element insulating layer INF may be formed of a single-layer structure or a double-layer structure, but embodiments are not limited thereto. The element insulating layer INF may be formed of a plurality of layers. For example, the element insulating layer INF may include a first insulating layer including a first material, and a second insulating layer including a second material different from the first material.

The element insulating layer INF may expose the opposite end portions of the light emitting element LD which have different polarities to the outside. For example, the element insulating layer INF may expose an end portion of each of the electrode layer ELL and the second semiconductor layer SCL2 which are adjacent to the first and second end portions EP1 and EP2 of the light emitting element LD.

The element insulating layer INF may include an insulating material among silicon oxide (SiOₓ), silicon nitride (SiNₓ), silicon oxynitride (SiOₓN_{y}), aluminum oxide (AlOₓ), and titanium oxide (TiOₓ). The element insulating layer INF may have a single-layer structure or a multi-layer structure. However, embodiments are not limited thereto. For example, in an embodiment, the formation of the element insulating layer INF may be omitted.

In an embodiment, in the case where the element insulating layer INF covers a surface of the light emitting element LD, an outer surface of the active layer AL, electrical stability of the light emitting element LD may be secured. Furthermore, in case that the element insulating layer INF is disposed on the surface of the light emitting element LD, occurrence of a defect on the surface of the light emitting element LD may be minimized, whereby the lifetime and efficiency of the light emitting element LD may be improved. Even in case that a plurality of light emitting elements LD are disposed adjacent to each other, an undesired short-circuit may be prevented from occurring between the light emitting elements LD.

The electrode layer ELL may be disposed on the first semiconductor layer SCL1. The electrode layer ELL may be adjacent to the first end portion EP1. The electrode layer ELL may be connected (e.g., electrically connected) to the first semiconductor layer SCL1.

A portion of the electrode layer ELL may be exposed. For example, the element insulating layer INF may expose a surface of the electrode layer ELL. The electrode layer ELL may be exposed in an area corresponding to the first end portion EP1.

In an embodiment, a side surface of the electrode layer ELL may be exposed. For example, the element insulating layer INF may cover a side surface of each of the first semiconductor layer SCL1, the active layer AL, and the second semiconductor layer SCL2, and may not cover at least a portion of the side surface of the electrode layer ELL. For example, electrical connection for other components of the electrode layer ELL adjacent to the first end portion EP1 may be facilitated. In an embodiment, the element insulating layer INF may expose not only the side surface of the electrode layer ELL but also a portion of the side surface of the first semiconductor layer SCL1 and/or the second semiconductor layer SCL2.

In an embodiment, the electrode layer ELL may be an ohmic contact electrode. However, embodiments are not limited thereto. For example, the electrode layer ELL may be a Schottky contact electrode.

In an embodiment, the electrode layer ELL may include one of chrome (Cr), titanium (Ti), aluminum (Al), gold (Au), nickel (Ni), and oxide or an alloy thereof. However, embodiments are not limited thereto. In an embodiment, the electrode layer 14 may be substantially transparent. For example, the electrode layer ELL may include indium tin oxide (ITO). Hence, the emitted light may pass through the electrode layer ELL.

The structure, the shape, and the like of the light emitting element LD are not limited to the foregoing examples. In an embodiment, the light emitting element LD may have various structures and shapes. For example, the light emitting element LD may further include an additional electrode layer which is disposed on a surface of the second semiconductor layer SCL2 and is adjacent to the second end portion EP2.

FIG. 3 is a schematic plan view illustrating a display device in accordance with an embodiment. For example, FIG. 3 illustrates a display device DD including a display panel DP. To explain the display device DD, the term “display panel DP” may be used, or to explain the display panel DP, the term “display device DD” may be used.

Referring to FIG. 3, the display device DD (or the display panel DP) may include a base layer BSL, and pixels PXL disposed on the base layer BSL. For example, the display device DD may further include a driving circuit component (e.g., a scan driver and a data driver), lines, and pads which drive the pixels PXL.

The display device DD may include a display area DA and a non-display area NDA. The non-display area NDA may refer to an area other than the display area DA. The non-display area NDA may enclose (or surround) at least a portion of the display area DA.

The base layer BSL may form a base of the display device DD. The base layer BSL may be a rigid substrate, a flexible substrate, or a film. For example, the base layer BSL may be a rigid substrate made of glass or reinforced glass, a flexible substrate (or a thin film) formed of plastic or metal, or at least one insulating layer. The material and/or properties of the base layer BSL are not limited thereto. In an embodiment, the base layer BSL may be substantially transparent. For example, the words “substantially transparent” means that light may pass through the substrate SUB at a certain transmissivity or more. In an embodiment, the base layer BSL may be translucent or opaque. Furthermore, the base layer BSL may include a reflective material in some embodiments.

The display area DA may refer to an area in which the pixels PXL are disposed. The non-display area NDA may refer to an area in which the pixels PXL are not disposed. The driving circuit layer, the lines, and the pads which are connected to the pixels PXL of the display area DA may be disposed in the non-display area NDA.

In an embodiment, the pixels PXL may be arranged in a stripe or PENTILE™ arrangement structure or the like, but embodiments are not limited thereto.

In an embodiment, the pixel PXL may include a first sub-pixel SPXL1, a second sub-pixel SPXL2, and a third sub-pixel SPXL3. The first sub-pixel SPXL1, the second sub-pixel SPXL2, and the third sub-pixel SPXL3 each may be a sub-pixel. At least one first sub-pixel SPXL1, at least one second sub-pixel SPXL2, and at least one third sub-pixel SPXL3 may form a pixel unit which may emit various colors of light.

For example, the first sub-pixel SPXL1, the second sub-pixel SPXL2, and the third sub-pixel SPXL3 each may emit a certain color of light. For instance, the first sub-pixel SPXL1 may be a red pixel that emits red (e.g., first color) light, the second sub-pixel SPXL2 may be a green pixel that emits green (e.g., second color) light, and the third sub-pixel SPXL3 may be a blue pixel that emits blue (e.g., third color) light. In an embodiment, the number of second sub-pixels SPXL2 may be greater than the number of first sub-pixel SPXL1, and the number of third sub-pixels SPXL3. However, the color, type, and/or number of the first sub-pixel SPXL1, the second sub-pixel SPXL2, and the third sub-pixel SPXL3 which form each pixel unit is not limited to a specific example.

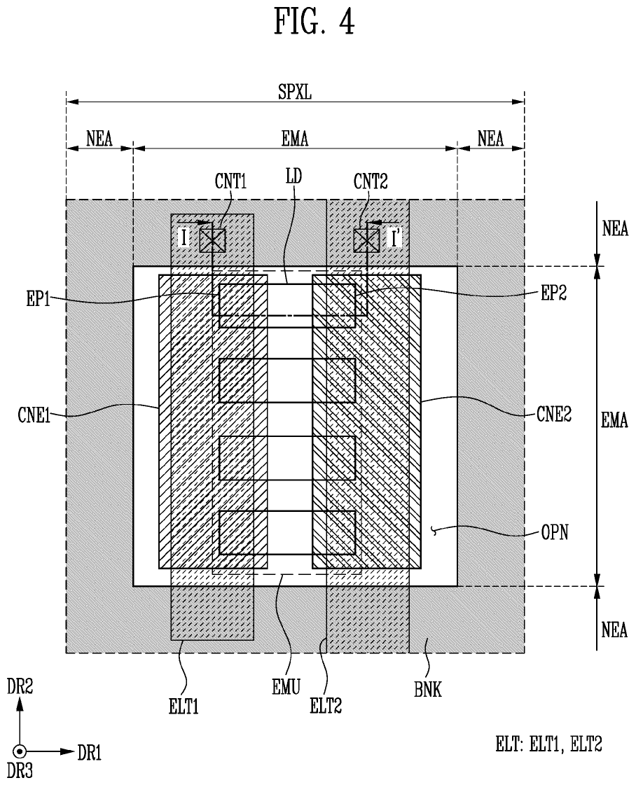

A pixel PXL (or a sub-pixel SPXL) in accordance with an embodiment will be described with reference to FIGS. 4 to 7. FIGS. 4 to 7 are diagrams illustrating the pixel PXL (or the sub-pixel SPXL) in accordance with an embodiment. Redundant descriptions will be simplified, or may not be repeated to avoid redundancy.

First, a planar structure of the sub-pixel SPXL will be described with reference to FIG. 4. FIG. 4 is a schematic plan view illustrating the sub-pixel SPXL in accordance with an embodiment. The sub-pixel SPXL illustrated in FIG. 4 may be one of the first to third sub-pixels SPXL1, SPXL2, and SPXL3 described above with reference to FIG. 3.

The sub-pixel SPXL may include an emission area EMA and a non-emission area NEA. The sub-pixel SPXL may include a bank BNK, an alignment electrode ELT, a light emitting element LD, a first contact electrode CNE1, and a second contact electrode CNE2.

In a plan view, the emission area EMA may overlap an opening OPN defined by the bank BNK. Light emitting elements LD may be disposed in the emission area EMA.

The light emitting elements LD may not be disposed in the non-emission area NEA. A portion of the non-emission area NEA may overlap the bank BNK in a plan view.

The bank BNK may form (or provide) an opening OPN. For example, the bank BNK may have a shape, protruding in a thickness direction of the base layer BSL (e.g., in a third direction DR3), and may have a shape, enclosing a certain area. Hence, the opening OPN in which the bank BNK is not disposed may be formed.

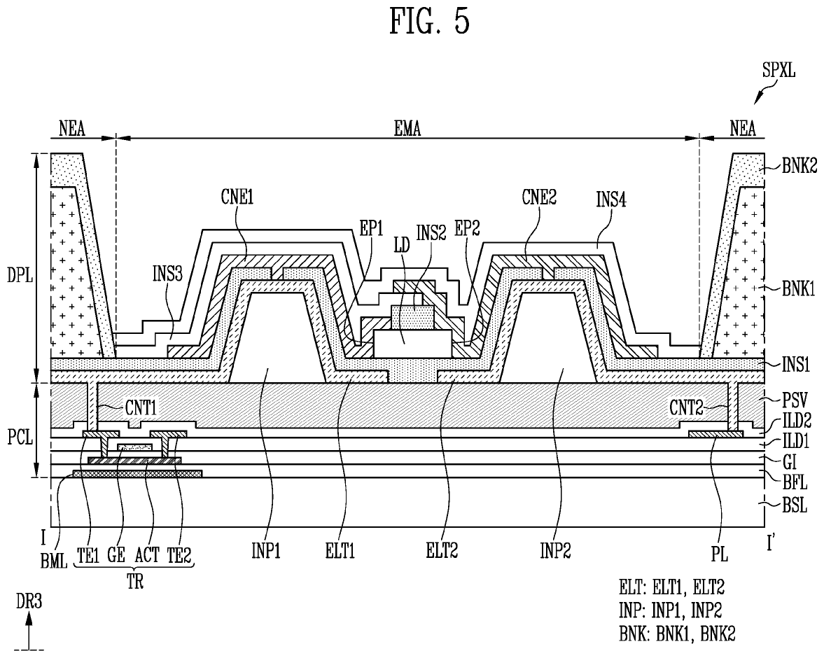

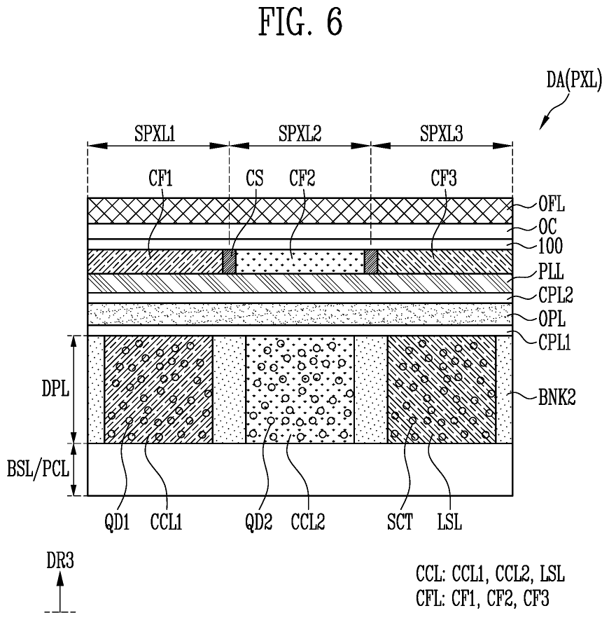

The bank BNK may form space. In a plan view, the bank BNK may have a shape, enclosing some areas. The space may refer to an area in which fluid may be received. In an embodiment, the bank BNK may include a first bank (refer to ‘BNK1’ of FIG. 5) and a second bank (refer to ‘BNK2’ of FIG. 6).

In an embodiment, ink including light emitting elements LD may be provided to the space formed by the bank BNK (for example, the first bank BNK1), so that the light emitting elements LD may be disposed in the opening OPN.

In an embodiment, a color conversion layer (refer to ‘CCL’ of FIG. 6) may be disposed (or patterned) in the space formed by the bank BNK (e.g., the second bank BNK2).

The bank BNK may define the emission area EMA and the non-emission area NEA. In a plan view, the bank BNK may enclose (or surround) at least a portion of the emission area EMA. For example, an area where the bank BNK is disposed may correspond to (or overlap) the non-emission area NEA. As an area where the bank BNK is not disposed, an area where the light emitting elements LD are disposed may correspond to (or overlap) the emission area EMA.

The alignment electrode ELT may be an electrode for aligning the light emitting elements LD. In an embodiment, the alignment electrode ELT may include a first electrode ELT1 and a second electrode ELT2. The alignment electrode ELT may be referred to as “electrode” or “electrodes”.

The alignment electrode ELT may have a single-layer structure or a multi-layer structure. For example, the alignment electrode ELT may include at least one reflective electrode layer including a reflective conductive material, and selectively further include at least one transparent electrode layer and/or a conductive capping layer. In an embodiment, the alignment electrode ELT may include one of silver (Ag), magnesium (Mg), aluminum (Al), platinum (Pt), palladium (Pd), gold (Au), nickel (Ni), neodymium (Nd), iridium (Ir), chrome (Cr), titanium (Ti), and an alloy thereof. However, embodiments are not limited thereto, and the alignment electrode ELT may include one of various materials having reflectivity. However, embodiments are not limited thereto.

The light emitting elements LD may be disposed on the alignment electrode ELT. In an embodiment, at least some of the light emitting elements LD may be disposed between the first electrode ELT1 and the second electrode ELT2. The light emitting elements LD may be aligned between the first electrode ELT1 and the second electrode ELT2. The light emitting elements LD may form (or constitute) an emission unit EMU. The emission unit EMU may refer to a unit embracing (or surrounding) light emitting elements LD adjacent to each other.

In an embodiment, the light emitting elements LD may be aligned in various ways. For example, FIG. 4 illustrates an embodiment in which the light emitting elements LD are aligned in parallel between the first electrode ELT1 and the second electrode ELT2. However, embodiments are not limited thereto. For example, the light emitting elements LD may be aligned in series or may have series/parallel combination structure, and the number of units which are connected in series and/or parallel to each other is not limited to a specific number.

The first electrode ELT1 and the second electrode ELT2 may be spaced apart from each other. For example, the first electrode ELT1 and the second electrode ELT2 may be spaced apart from each other in a first direction DR1 in the emission area EMA, and each of the first electrode ELT1 and the second electrode ELT2 may extend in a second direction DR2.

In an embodiment, the first electrode ELT1 and the second electrode ELT2 may be electrodes for aligning the light emitting elements LD. The first electrode ELT1 may be a first alignment electrode. The second electrode ELT2 may be a second alignment electrode.

The first electrode ELT1 and the second electrode ELT2 may be respectively supplied (or provided) with a first alignment signal and a second alignment signal during a process of aligning the light emitting elements LD. For example, ink including the light emitting elements LD may be supplied (or provided) to the opening OPN defined by the bank BNK (e.g., the first bank BNK1), the first alignment signal may be supplied to the first electrode ELT1, and the second alignment signal may be supplied to the second electrode ELT2. The light emitting elements LD may be aligned by an electric field formed based on the first alignment signal and the second alignment signal.

The first electrode ELT1 may be connected (e.g., electrically connected) to a circuit element (e.g., a transistor TR of FIG. 5) through a first contact CNT1. In an embodiment, the first electrode ELT1 may provide an anode signal to emit light by the light emitting elements LD. The first electrode ELT1 may provide a first alignment signal to align the light emitting elements LD.

The second electrode ELT2 may be connected (e.g., electrically connected) to a power line PL of FIG. 5 through a second contact CNT2. In an embodiment, the second electrode ELT2 may provide a cathode signal to emit light by the light emitting elements LD. The second electrode ELT2 may provide a second alignment signal to align the light emitting elements LD.

The positions of the first contact CNT1 and the second contact CNT2 are not limited to the positions illustrated in FIG. 4, and may be appropriately changed in various ways.

The light emitting element LD may emit light based on a provided electrical signal. For example, the light emitting element LD may provide light based on a first electrical signal (for example, an anode signal) provided from the first contact electrode CNE1 and a second electrical signal (for example, a cathode signal) provided from the second contact electrode CNE2.

The first end portion EP1 of the light emitting element LD may be disposed adjacent to the first electrode ELT1. The second end portion EP2 of the light emitting element LD may be disposed adjacent to the second electrode ELT2. The first end portion EP1 may or may not overlap the first electrode ELT1. The second end portion EP2 may or may not overlap the second electrode ELT2.

In an embodiment, the respective first end portions EP1 of the light emitting elements LD may be connected (e.g., electrically connected) to the first electrode ELT1 through the first contact electrode CNE1. In an embodiment, the respective first end portions EP1 of the light emitting elements LD may be connected (e.g., directly connected) to the first electrode ELT1. In an embodiment, the respective first end portions EP1 of the light emitting elements LD may be connected (e.g., electrically connected) to only the first contact electrode CNE1, rather than being connected to the first electrode ELT1.

Likewise, the respective second end portions EP2 of the light emitting elements LD may be connected (e.g., electrically connected) to the second electrode ELT2 through the second contact electrode CNE2. In an embodiment, the respective second end portions EP2 of the light emitting elements LD may be connected (e.g., directly connected) to the second electrode ELT2. In an embodiment, the respective second end portions EP2 of the light emitting elements LD may be connected (e.g., electrically connected) to only the second contact electrode CNE2, rather than being connected to the second electrode ELT2.

The first contact electrode CNE1 and the second contact electrode CNE2 may be respectively disposed on the first end portions EP1 and the second end portions EP2 of the light emitting elements LD.

The first contact electrode CNE1 may be disposed on the first end portions EP1 of the light emitting elements LD such that the first contact electrode CNE1 may be connected (e.g., electrically connected) to the first end portions EP1. In an embodiment, the first contact electrode CNE1 may be disposed on the first electrode ELT1 and connected (e.g., electrically connected) to the first electrode ELT1. For example, the first end portions EP1 of the light emitting elements LD may be connected (e.g., electrically connected) to the first electrode ELT1 through the first contact electrode CNE1.

The second contact electrode CNE2 may be disposed on the second end portions EP2 of the light emitting elements LD such that the second contact electrode CNE2 may be connected (e.g., electrically connected) to the second end portions EP2. In an embodiment, the second contact electrode CNE2 may be disposed on the second electrode ELT2 and connected (e.g., electrically connected) to the second electrode ELT2. For example, the second end portions EP2 of the light emitting elements LD may be connected (e.g., electrically connected) to the second electrode ELT2 through the second contact electrode CNE2.

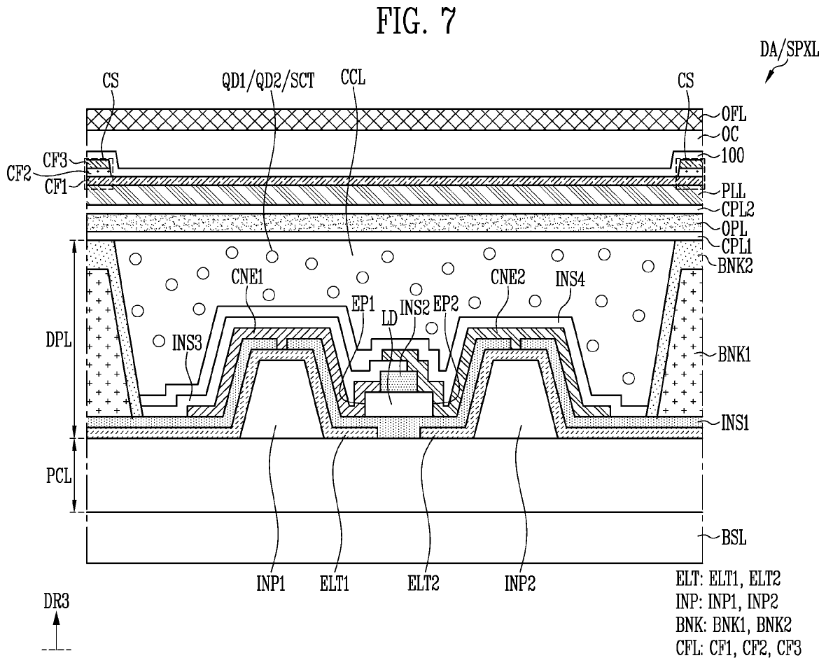

A cross-sectional structure of the pixel PXL (or the sub-pixel SPXL) in accordance with an embodiment will be described with reference to FIGS. 5 to 7. In detail, the pixel circuit layer PCL and the display element layer DPL of the sub-pixel SPXL will be described with reference to FIG. 5. Referring to FIGS. 6 and 7, an optical layer OPL, a color filter layer CFL, and an outer film layer OFL will be described with reference to FIGS. 6 and 7. Redundant descriptions will be simplified, or may not be repeated to avoid redundancy.

FIG. 5 is a schematic sectional view illustrating the sub-pixel SPXL in accordance with an embodiment. FIG. 6 is a schematic sectional view illustrating the pixel PXL in accordance with an embodiment. FIG. 7 is a schematic sectional view illustrating the sub-pixel SPXL in accordance with an embodiment.

Referring to FIG. 5, the sub-pixel SPXL may be disposed on the base layer BSL. The sub-pixel SPXL may include a pixel circuit layer PCL and a display element layer DPL.

The base layer BSL may form a base for forming the sub-pixel SPXL. The base layer BSL may provide an area formed to dispose the pixel circuit layer PCL and the display element layer DPL therein.

The pixel circuit layer PCL may be disposed on the base layer BSL. The pixel circuit layer PCL may include an auxiliary bottom electrode BML, a buffer layer BFL, a transistor TR, a gate insulating layer GI, a first interlayer insulating layer ILD1, a second interlayer insulating layer ILD2, and a passivation layer PSV.

The auxiliary bottom electrode BML may be disposed on the base layer BSL. The auxiliary bottom electrode BML may function as a path along which an electrical signal is transmitted. In an embodiment, a portion of the auxiliary bottom electrode BML may overlap the transistor TR, in a plan view.

The buffer layer BFL may be disposed on the base layer BSL. The buffer layer BFL may cover the auxiliary bottom electrode BML. The buffer layer BFL may prevent impurities from diffusing from the outside. The buffer layer BFL may include one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The transistor TR may be a thin film transistor. In an embodiment, the transistor TR may be a driving transistor. The transistor TR may be connected (e.g., electrically connected) to the light emitting element LD. The transistor TR may be connected (e.g., electrically connected) to the first end portion EP1 of the light emitting element LD.

The transistor TR may include an active layer ACT, a first transistor electrode TE1, a second transistor electrode TE2, and a gate electrode GE.

The active layer ACT may refer to a semiconductor layer. The active layer ACT may be disposed on the buffer layer BFL. The active layer ACT may include one selected from the group consisting of polysilicon, low temperature polycrystalline silicon (LTPS), amorphous silicon, and an oxide semiconductor.

The active layer ACT may include a first contact area which contacts the first transistor electrode TE1, and a second contact area which contacts the second transistor electrode TE2. Each of the first contact area and the second contact area may be a semiconductor pattern doped with an impurity. An area between the first contact area and the second contact area may be a channel area. The channel area may be an intrinsic semiconductor pattern which is not doped with an impurity.

The gate electrode GE may be disposed on the gate insulating layer GI. The position of the gate electrode GE may correspond to (or overlap) the position of the channel area of the active layer ACT. For example, the gate electrode GE may be disposed on the channel area of the active layer ACT with the gate insulating layer GI interposed therebetween.

The gate insulating layer GI may be disposed on the buffer layer BFL. The gate insulating layer GI may cover the active layer ACT. The gate insulating layer GI may include one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The first interlayer insulating layer ILD1 may be disposed on the gate insulating layer GI. The first interlayer insulating layer ILD1 may cover the gate electrode GE. The first interlayer insulating layer ILD1 may include one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The first transistor electrode TE1 and the second transistor electrode TE2 may be disposed on the first interlayer insulating layer ILD1. The first transistor electrode TE1 may contact the first contact area of the active layer ACT through the gate insulating layer GI and the first interlayer insulating layer ILD1. The second transistor electrode TE2 may contact the second contact area of the active layer ACT through the gate insulating layer GI and the first interlayer insulating layer ILD1. For example, the first transistor electrode TE1 may be a drain electrode, and the second transistor electrode TE2 may be a source electrode, but embodiments are not limited thereto.

The first transistor electrode TE1 may be connected (e.g., electrically connected) to the first electrode ELT1 through the first contact CNT1 passing through the passivation layer PSV and the second interlayer insulating layer ILD2.

The power line PL may be disposed on the first interlayer insulating layer ILD1. In an embodiment, the power line PL, the first transistor electrode TE1, and the second transistor electrode TE2 may be disposed on a same layer. The power line PL may be connected (e.g., electrically connected) to the second electrode ELT2 through the second contact CNT2. The power line PL may supply power or an alignment signal through the second electrode ELT2.

The second interlayer insulating layer ILD2 may be disposed on the first interlayer insulating layer ILD1. The second interlayer insulating layer ILD2 may cover the first transistor electrode TE1, the second transistor electrode TE2, and the power line PL. The second interlayer insulating layer ILD2 may include one of silicon oxide (SiOₓ), silicon nitride (SiNₓ), silicon oxynitride (SiOₓN_{y}), aluminum oxide (AlOₓ), and titanium oxide (TiOₓ). However, embodiments are not limited thereto.

The passivation layer PSV may be disposed on the second interlayer insulating layer ILD2. In embodiments, the passivation layer PSV may be a via layer. The passivation layer PSV may include an organic material for planarizing a stepped structure provided therebelow. For example, the passivation layer PSV may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The passivation layer PSV may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the sub-pixel SPXL may include a first contact CNT1 and a second contact CNT2. The first contact CNT1 and the second contact CNT2 each may pass through the second interlayer insulating layer ILD2 and the passivation layer PSV. The first electrode ELT1 and the first transistor electrode TE1 may be connected (e.g., electrically connected) to each other through the first contact CNT1. The second electrode ELT2 and the power line PL may be connected (e.g., electrically connected) to each other through the second contact CNT2.

The display element layer DPL may be disposed on the pixel circuit layer PCL. The display element layer DPL may include a first insulating layer INS1, an insulating pattern INP, an alignment electrode ELT, a bank BNK, a light emitting element LD, a second insulating layer INS2, a first contact electrode CNE1, a third insulating layer INS3, a second contact electrode CNE2, and a fourth insulating layer INS4.

The insulating pattern INP may be disposed on the passivation layer PSV. For example, the insulating pattern INP may have various shapes. In an embodiment, the insulating pattern INP may protrude in a thickness direction of the base layer BSL (e.g., the third direction DR3). Furthermore, the insulating pattern INP may have an inclined surface which is inclined at a certain angle with respect to the base layer BSL. However, embodiments are not limited thereto. The insulating pattern INP may have a sidewall having a curved or stepped shape. For example, the insulating pattern INP may have a cross-sectional shape such as a semi-circular or semi-elliptical shape.

The insulating pattern INP may function to form a certain step difference so that the light emitting elements LD may be readily aligned in the emission area. In an embodiment, the insulating pattern INP may be a partition wall.

In an embodiment, a portion of the alignment electrode ELT may be disposed on the insulating pattern INP. For example, the insulating pattern INP may include a first insulating pattern INP1 and a second insulating pattern INP2. The first electrode ELT1 may be disposed on the first insulating pattern INP1. The second electrode ELT2 may be disposed on the second insulating pattern INP2. Hence, a reflective wall may be formed on the insulating pattern INP. Accordingly, light emitted from the light emitting element LD may be recycled, so that the light output efficiency of the display device DD (or the pixel PXL) may be improved.

The insulating pattern INP may include at least one organic material and/or inorganic material. For example, the insulating pattern INP may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The insulating pattern INP may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The alignment electrode ELT may be disposed on the passivation layer PSV and/or the insulating pattern INP. As described above, a portion of the alignment electrode ELT may be disposed on the insulating pattern INP, thus forming a reflective wall. Alignment signals (e.g., an AC signal and a ground signal) for aligning the light emitting elements LD may be supplied to the alignment electrodes ELT. In an embodiment, electrical signals (e.g., an anode signal and a cathode signal) may be supplied to the alignment electrodes ELT to emit light by the light emitting element LD.

In an embodiment, the alignment electrode ELT may be disposed on a rear surface of the first insulating layer INS1. For example, the alignment electrode ELT may be disposed between the first insulating layer INS1 and the insulating pattern INP or the passivation layer PSV. For example, a surface of the alignment electrode ELT may contact the first insulating layer INS1.

The first electrode ELT1 may be connected (e.g., electrically connected) to the light emitting element LD. The first electrode ELT1 may be connected (e.g., electrically connected) to the first contact electrode CNE1 through a contact hole formed in the first insulating layer INS1. The first electrode ELT1 may provide an anode signal needed for the light emitting elements LD to emit light.

The second electrode ELT2 may be connected (e.g., electrically connected) to the light emitting element LD. The second electrode ELT2 may be connected (e.g., electrically connected) to the second contact electrode CNE2 through a contact hole formed in the first insulating layer INS1. The second electrode ELT2 may provide a cathode signal (e.g., a ground signal) needed for the light emitting element LD to emit light.

The first insulating layer INS1 may be disposed on the alignment electrode ELT. For example, the first insulating layer INS1 may cover the first electrode ELT1 and the second electrode ELT2.

The bank BNK may be disposed on the first insulating layer INS1. In an embodiment, the bank BNK may include a first bank BNK1 and a second bank BNK2.

The first bank BNK1 may be disposed on the first insulating layer INS1. In an embodiment, in a plan view, the first bank BNK1 may not overlap the emission area EMA, and may overlap the non-emission area NEA. As described above, the first bank BNK1 may protrude in the thickness direction of the base layer BSL (e.g., in the third directionDR3), so that the first bank BNK1 may define an opening OPN. Space to which the light emitting elements LD may be provided during a process of supplying the light emitting elements LD may be formed in the opening OPN

The first bank BNK1 may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The first bank BNK1 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The second bank BNK2 may be disposed on the first bank BNK1. The second bank BNK2 may protrude in the thickness direction of the base layer BSL (e.g., in the third direction DR3), so that the second bank BNK2 may define an opening OPN. Space to which the color conversion layer CCL is to be provided may be formed in the opening OPN.

The second bank BNK2 may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The second bank BNK2 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The light emitting elements LD may be disposed on the first insulating layer INS1. In an embodiment, the light emitting element LD may emit light based on electrical signals (e.g., an anode signal and a cathode signal) provided from the first contact electrode CNE1 and the second contact electrode CNE2.

The light emitting element LD may be disposed in an area enclosed (or surrounded) by the first bank BNK1. The light emitting element LD may be disposed between the first insulating pattern INP1 and the second insulating pattern INP2.

The second insulating layer INS2 may be disposed on the light emitting elements LD. The second insulating layer INS2 may cover the active layer 12 of the light emitting element LD.

The second insulating layer INS2 may expose at least a portion of the light emitting element LD. For example, the second insulating layer INS2 may not cover the first end portion EP1 and the second end portion EP2 of the light emitting element LD. Hence, the first end portion EP1 and the second end portion EP2 of the light emitting element LD may be exposed and respectively connected (e.g., electrically connected) to the first contact electrode CNE1 and the second contact electrode CNE2.

In the case in which the second insulating layer INS2 is formed on the light emitting elements LD after the alignment of the light emitting elements LD have been completed, the light emitting elements LD may be prevented from being removed from the aligned positions.

The second insulating layer INS2 may have a single-layer structure or a multi-layer structure. The second insulating layer INS2 may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). However, embodiments are not limited thereto.

The first contact electrode CNE1 and the second contact electrode CNE2 may be disposed on the first insulating layer INS1. The first contact electrode CNE1 may be connected (e.g., electrically connected) to the first end portion EP1 of the light emitting element LD. The second contact electrode CNE2 may be connected (e.g., electrically connected) to the second end portion EP2 of the light emitting element LD.

The first contact electrode CNE1 may be connected (e.g., electrically connected) to the first electrode ELT1 through a contact hole passing through the first insulating layer INS1. The second contact electrode CNE2 may be connected (e.g., electrically connected) to the second electrode ELT2 through a contact hole passing through the first insulating layer INS1.

The first contact electrode CNE1 and the second contact electrode CNE2 may include a conductive material. For example, the first contact electrode CNE1 and the second contact electrode CNE2 may include a transparent conductive material including one of indium tin oxide (ITO), indium zinc oxide (IZO), and indium tin zinc oxide (ITZO), but embodiments are not limited thereto. Hence, light emitted from the light emitting elements LD may be emitted out of the display device DD after passing through the first and second contact electrodes CNE1 and CNE2. However, embodiments are not limited thereto.

In an embodiment, after any one of the first contact electrode CNE1 and the second contact electrode CNE2 is patterned, the other electrode may be patterned. However, embodiments are not limited thereto. The first contact electrode CNE1 and the second contact electrode CNE2 may be simultaneously patterned at a same time by a same process.

The third insulating layer INS3 may be disposed on the first insulating layer INS1 and the first contact electrode CNE1. At least a portion of the third insulating layer INS3 may be disposed between the first contact electrode CNE1 and the second contact electrode CNE2, so that a short-circuit defect between the first contact electrode CNE1 and the second contact electrode CNE2 may be prevented from occurring.

The fourth insulating layer INS4 may be disposed on the third insulating layer INS3 and the second contact electrode CNE2. The fourth insulating layer INS4 may protect the components of the display element layer DPL from an external influence.

The third insulating layer INS3 and the fourth insulating layer INS4 each may have a single-layer structure or a multi-layer structure. The third insulating layer INS3 and the fourth insulating layer INS4 each may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The components of the pixel PXL including the color conversion layer CCL will be described with reference to FIGS. 6 and 7. FIG. 6 illustrates a color conversion layer CCL, an optical layer OPL, a color filter layer CFL, and the like. For convenience of description, in FIG. 6, among the above-mentioned components, the components of the pixel circuit layer PCL and the components of the display element layer DPL other than the second bank BNK2 will be omitted. FIG. 7 illustrates a stacked structure of the sub-pixel SPXL with regard to the color conversion layer CCL, the optical layer OPL, and the color filter layer CFL. For convenience of description, FIG. 7 illustrates the first sub-pixel SPXL1 in accordance with an embodiment.

Referring to FIGS. 6 and 7, the second bank BNK2 may be disposed between the first to third sub-pixels SPXL1, SPXL2, and SPXL3 or on boundaries therebetween, and define space (or areas) which respectively overlap the first to third sub-pixels SPXL1, SPXL2, and SPXL3. The space formed by the second bank BNK2 may provide an area in which the color conversion layer CCL is provided.

The color conversion layer CCL may be disposed on the light emitting elements LD in the space enclosed by the second bank BNK2. The color conversion layer CCL may include a first color conversion layer CCL1 disposed in the first sub-pixel SPXL1, a second color conversion layer CCL2 disposed in the second sub-pixel SPXL2, and a light scattering layer LSL disposed in the third sub-pixel SPXL3.

The color conversion layer CCL may be disposed on the light emitting element LD. The color conversion layer CCL may be formed to change the wavelength of light. In an embodiment, the first to third sub-pixels SPXL1, SPXL2, and SPXL3 may include light emitting elements LD that emit a same color of light. For example, the first to third sub-pixels SPXL1, SPXL2, and SPXL3 may include light emitting elements LD that emit the third color of light (or blue light). Because the color conversion layer CCL including color conversion particles is disposed in each of the first to third sub-pixels SPXL1, SPXL2, and SPXL3, a full-color image may be displayed.

The first color conversion layer CCL1 may include first color conversion particles for converting the third color of light emitted from the light emitting element LD to the first color of light. For example, the first color conversion layer CCL1 may include first quantum dots QD1 which are dispersed in a matrix material such as base resin.

In an embodiment, in case that the light emitting element LD is a blue light emitting element that emits blue light and the first sub-pixel SPXL1 is a red pixel, the first color conversion layer CCL1 may include the first quantum dots QD1 which may convert blue light emitted from the blue light emitting element to red light. The first quantum dots QD1 may absorb blue light, shift the wavelength thereof according to an energy transition, and thus emit red light. In case that the first sub-pixel SPXL1 is one of pixels of other colors, the first color conversion layer CCL1 may include the first quantum dots QD1 corresponding to the color of the first sub-pixel SPXL1.

The second color conversion layer CCL2 may include second color conversion particles for converting the third color of light emitted from the light emitting element LD to the second color of light. For example, the second color conversion layer CCL2 may include second quantum dots QD2 which are dispersed in a matrix material such as base resin.

In an embodiment, in case that the light emitting element LD is a blue light emitting element that emits blue light and the second sub-pixel SPXL2 is a green pixel, the second color conversion layer CCL2 may include the second quantum dots QD2 which may convert blue light emitted from the blue light emitting element to green light. The second quantum dots QD2 may absorb blue light, shift the wavelength thereof according to an energy transition, and thus emit green light. In case that the second sub-pixel SPXL2 is one of pixels of other colors, the second color conversion layer CCL2 may include the second quantum dots QD2 corresponding to the color of the second sub-pixel SPXL2.

In an embodiment, as blue light having a relatively short wavelength in a visible ray range is incident on each of the first quantum dots QD1 and the second quantum dots QD2, absorption coefficients of the first quantum dot QD1 and the second quantum dot QD2 may be increased. Therefore, the efficiency of light emitted from the first sub-pixel SPXL1 and the second sub-pixel SPXL2 may be enhanced, and satisfactory color reproducibility may be implemented. Furthermore, because the emission unit EMU for the first to third sub-pixels SPXL1, SPXL2, and SPXL3 is formed of light emitting elements LD (e.g., blue light emitting elements) that emits a same color of light, the efficiency of fabricating the display device DD may be enhanced.

The light scattering layer LSL may be provided to efficiently use the third color of light (or blue light) emitted from the light emitting element LD. For example, in case that the light emitting element LD is a blue light emitting element that emits blue light and the third sub-pixel SPXL3 is a blue pixel, the light scattering layer LSL may include at least one type of light scatterer SCT to efficiently use light emitted from the light emitting element LD. For example, the light scatterer SCT of the light scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). The light scatterers SCT may not only be provided in the third sub-pixel SPXL3, but may also be selectively included in the first color conversion layer CCL1 or the second color conversion layer CCL2. In an embodiment, the light scatterers SCT may be omitted, and the light scattering layer LSL may be formed of transparent polymer.

A first capping layer CPL1 may be disposed on the color conversion layer CCL. The first capping layer CPL1 may be disposed over the first to third sub-pixels SPXL1, SPXL2, and SPXL3. The first capping layer CPL1 may cover the color conversion layer CCL. The first capping layer CPL1 may prevent the color conversion layer CCL from being damaged or contaminated by permeation of external impurities such as water or air.

The first capping layer CPL1 may include an inorganic material. For example, the first capping layer CPL1 may include one or more selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}). However, embodiments are not limited thereto.

The optical layer OPL may be disposed on the first capping layer CPL1. The optical layer OPL may function to recycle light provided from the color conversion layer CCL by total reflection and thus enhance light extraction efficiency. Hence, the optical layer OPL may have a relatively low refractive index compared to that of the color conversion layer CCL. For example, the refractive index of the color conversion layer CCL may be in a range of about 1.6 to about 2.0, and the refractive index of the optical layer OPL may be in a range of about 1.1 to about 1.3.

A second capping layer CPL2 may be disposed on the optical layer OPL. The second capping layer CPL2 may be disposed over the first to third sub-pixels SPXL1, SPXL2, and SPXL3. The second capping layer CPL2 may cover the optical layer OPL. The second capping layer CPL2 may prevent the optical layer OPL from being damaged or contaminated by permeation of external impurities such as water or air.

The second capping layer CPL2 may include an inorganic material.

For example, the second capping layer CPL2 may include one or more selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}). However, embodiments are not limited thereto.

A planarization layer PLL may be disposed on the second capping layer CPL2. The planarization layer PLL may be disposed over the first to third sub-pixels SPXL1, SPXL2, and SPXL3.

The planarization layer PLL may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The planarization layer PLL may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 corresponding to the colors of the respective pixels PXL. Since the color filters CF1, CF2, and CF3 corresponding to the respective colors of the first to third sub-pixels SPXL1, SPXL2, and SPXL3 are disposed, a full-color image may be displayed.

The color filter layer CFL may include a first color filter CF1 which is disposed in the first sub-pixel SPXL1 and selectively passes (or transmits) light emitted from the first sub-pixel SPXL1 therethrough, a second color filter CF2 which is disposed in the second sub-pixel SPXL2 and selectively passes (or transmits) light emitted from the second sub-pixel SPXL2 therethrough, and a third color filter CF3 which is disposed in the third sub-pixel SPXL3 and selectively passes (or transmits) light emitted from the third sub-pixel SPXL3 therethrough.

In an embodiment, the first color filter CF1, the second color filter CF2, and the third color filter CF3 may be respectively a red color filter, a green color filter, and a blue color filter, but embodiments are not limited thereto. Hereinafter, the term “color filter CF” or “color filters CF” will be used to designate any color filter among the first color filter CF1, the second color filter CF2, and the third color filter CF3, or collectively designate two or more kinds of color filters.

The first color filter CF1 may overlap the first color conversion layer CCL1 in the thickness direction of the base layer BSL (e.g., the third direction DR3). The first color filter CF1 may include a color filter material for selectively passing the first color of light (or red light) therethrough. For example, in case that the first sub-pixel SPXL1 is a red pixel, the first color filter CF1 may include a red color filter material.

The second color filter CF2 may overlap the second color conversion layer CCL2 in the thickness direction of the base layer BSL (e.g., the third direction DR3). The second color filter CF2 may include a color filter material for selectively passing the second color of light (or green light) therethrough. For example, in case that the second sub-pixel SPXL2 is a green pixel, the second color filter CF2 may include a green color filter material.

The third color filter CF3 may overlap the light scattering layer LSL in the thickness direction of the base layer BSL (e.g., the third direction DR3). The third color filter CF3 may include a color filter material for selectively passing the third color of light (or blue light) therethrough. For example, in case that the third sub-pixel SPXL3 is a blue pixel, the third color filter CF3 may include a blue color filter material.

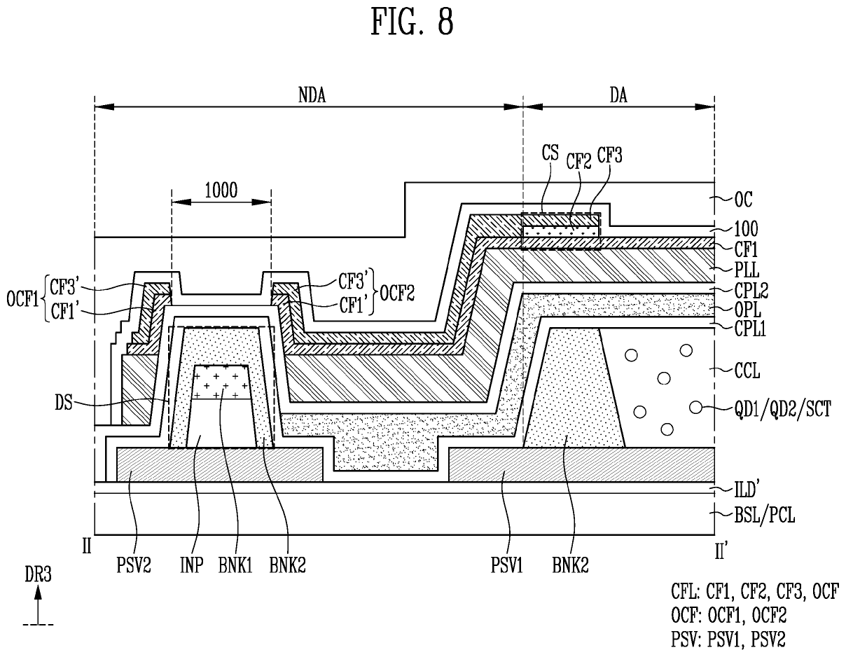

In an embodiment, a portion of the color filter layer CFL may be disposed in the non-display area NDA. For example, a portion of each of the first to third color filters CF1, CF2, and CF3 may be disposed in the non-display area NDA. Detailed description thereof will be made below with reference to FIG. 8.

In an embodiment, a light shielding layer CS formed by stacking the first to third color filters CF1, CF2, and CF3 may be disposed between the first to third sub-pixels SPXL1, SPXL2, and SPXL3. The light shielding layer CS has a structure in which the first to third color filters CF1, CF2, and CF3 are stacked, so that the light shielding layer CS may block light. In the case in which the light shielding layer CS is formed between the first to third sub-pixels SPXL1, SPXL2, and SPXL3, a color mixing defect which is visible from a front surface and/or a side surface of the display device DD may be prevented from occurring. The light shielding layer CS may have various light shielding materials, rather than having the foregoing structure. For example, the light shielding layer CS may include a black matrix.

A cover layer 100 may be disposed on the color filter layer CFL. The cover layer 100 may be disposed over the first to third sub-pixels SPXL1, SPXL2, and SPXL3. The cover layer 100 may be disposed between the overcoat layer OC and the color filter layer CFL. The cover layer 100 may cover the color filter layer CFL, and protect the color filter layer CFL from an external influence.

In an embodiment, the cover layer 100 may include an inorganic material. For example, the cover layer 100 may include one or more selected from the group consisting of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), or silicon oxynitride (SiOₓN_{y}). However, embodiments are not limited thereto.

In an embodiment, a portion of the cover layer 100 may be disposed in the non-display area NDA and cover the components disposed in the non-display area NDA. Detailed description thereof will be made below with reference to FIG. 8.

The overcoat layer OC may be disposed on the cover layer 100. The overcoat layer OC may be disposed over the first to third sub-pixels SPXL1, SPXL2, and SPXL3. The overcoat layer OC may cover a lower component including the color filter layer CFL. The overcoat layer OC may prevent water or air from permeating the lower component. Furthermore, the overcoat layer OC may protect the lower component from a foreign material such as dust.

The overcoat layer OC may include an organic material such as acrylic resin, epoxy resin, phenolic resin, polyamide resin, polyimide resin, polyester resin, polyphenylene sulfide resin, or benzocyclobutene (BCB). However, embodiments are not limited thereto. The overcoat layer OC may include various inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The outer film layer OFL may be disposed on the overcoat layer OC. The outer film layer OFL may be disposed on an outer portion of the display device DD (or the display panel DP). The outer film layer OFL may be disposed over the first to third sub-pixels SPXL1, SPXL2, and SPXL3. In an embodiment, the outer film layer OFL may include one of a polyethyleneterephthalate (PET) film, a low reflection film, a polarizing film, and a transmittance controllable film, but embodiments are not limited thereto.

An area where the non-display area NDA and the display area DA are adjacent to each other will be described with reference to FIG. 8, as a sectional structure of the display device DD in accordance with an embodiment. Redundant descriptions will be simplified, or may not be repeated to avoid redundancy.

FIG. 8 is a schematic sectional view illustrating the display device DD in accordance with an embodiment. FIG. 8 is a schematic sectional view taken along line II-II′ of FIG. 3. FIG. 8 illustrates the area where the display area DA and the non-display area NDA are adjacent to each other. For convenience of description, in FIG. 8, detailed illustrations of the light emitting element LD, the first electrode ELT1, the second electrode ELT2, the first insulating layer INS1, and the first bank BNK1 are omitted, and the color conversion layer CCL and the second bank BNK2 are illustrated. For convenience of description, detailed illustration of some components of the pixel circuit layer PCL is omitted. For example, a passivation layer PSV and an interlayer insulating layer ILD′ among the components of the pixel circuit layer PCL are illustrated. In an embodiment, the interlayer insulating layer ILD′ may refer to the second interlayer insulating layer ILD2 described above.

In an embodiment, FIG. 8 illustrates a structure pertaining to the display area DA and the non-display area NDA on a side (e.g., a left side) of the display area DA of FIG. 3. However, embodiments are not limited thereto. For example, technical characteristics to be described with reference to FIG. 8 may be similarly (or substantially identically) applied to the structure pertaining to the display area DA and the non-display area NDA on each of the left side, right side, upper side, and lower side of the display area DA.

Referring to FIG. 8, the display area DA and the non-display area NDA may be adjacent to each other. For example, the display area DA and the non-display area NDA may be divided from each other, based on a structure including the second bank BNK2 that is disposed in an outermost area (e.g., a perimeter) among the second banks BNK2 which may define the position at which the color conversion layer CCL is disposed. In another example, the display area DA and the non-display area NDA may be divided from each other, based on a layer that is disposed on the outermost area (e.g., the perimeter) among the light shielding layers CS.

The base layer BSL and the pixel circuit layer PCL may be disposed over the display area DA and the non-display area NDA. For example, the passivation layer PSV and the interlayer insulating layer ILD′ may be disposed in the display area DA and the non-display area NDA. The interlayer insulating layer ILD′ may refer to any one of insulating layers disposed under the passivation layer PSV. The interlayer insulating layer ILD′ may be disposed between the passivation layer PSV and the base layer BSL.

The passivation layer PSV may be disposed on the interlayer insulating layer ILD′. The passivation layer PSV may form an area in which the second bank BNK2 for patterning the color conversion layer CCL may be disposed in the display area DA, and may form an area in which a dam member DS may be disposed in the non-display area NDA.

In an embodiment, as described above, the passivation layer PSV may include an organic material, and may be a via layer. In an embodiment, the passivation layer PSV may be covered by the first capping layer CPL1. For example, a side surface of the passivation layer PSV that faces the outer portion of the display device DD (or the display panel DP) may be covered by the first capping layer CPL1. For example, the passivation layer PSV may not be exposed to the outside during a process of fabricating the display device DD, and an external influence (e.g., moisture) may be substantially prevented from being penetrated into individual components of the display device DD (or the display panel DP) through the passivation layer PSV.

In an embodiment, the passivation layer PSV may include a first passivation layer PSV1 disposed in the display area DA, and a second passivation layer PSV2 disposed in the non-display area NDA. The first passivation layer PSV1 and the second passivation layer PSV2 may be spaced apart from each other. In an embodiment, the first capping layer CPL1 and the interlayer insulating layer ILD′ may contact (e.g., directly contact) each other in an area by which the first passivation layer PSV1 and the second passivation layer PSV2 are spaced apart from each other. For example, in case that an external impurity permeates the second passivation layer PSV2, the external impurity may be prevented from permeating the display area DA because the first passivation layer PSV1 and the second passivation layer PSV2 are separated from each other, and the first capping layer CPL1 and the interlayer insulating layer ILD′ contact (e.g., directly contact) each other.

The second bank BNK2 formed in the display area DA may form an area in which the color conversion layer CCL is to be patterned. The color conversion layer CCL may be sealed (or encapsulated) by the first capping layer CPL1. The first capping layer CPL1 may be disposed over the display area DA and the non-display area NDA.

In an embodiment, the first capping layer CPL1 may contact (e.g., directly contact) an insulating layer (e.g., the interlayer insulating layer ILD′) of the pixel circuit layer PCL in the area by which the first passivation layer PSV1 and the second passivation layer PSV2 are spaced apart from each other. At least a portion of the first capping layer CPL1 may cover a side surface of the second passivation layer PSV2. At least a portion of the first capping layer CPL1 may cover a side surface of the dam member DS.

The dam member DS may be disposed in the non-display area NDA. The dam member DS may be disposed on the second passivation layer PSV2.

The dam member DS may protrude in the thickness direction of the base layer BSL (e.g., the third direction DR3). For example, the dam member DS may have a shape protruding in a direction. Hence, the dam member DS may substantially prevent layers (e.g., the optical layer OPL, the planarization layer PLL, and the like) formed inside the dam member DS from being exposed to the outside.

The dam member DS may include a second bank BNK2. For example, at least a portion of the dam member DS and the second bank BNK2 may include a same material. For example, the second bank BNK2 may enclose (or surround) the area in which the color conversion layer CCL is to be patterned. For example, the dam member DS may include an insulating pattern INP, a first bank BNK1, and a second bank BNK2. In an embodiment, the insulating pattern INP, the first bank BNK1, and the second bank BNK2 that form the dam member DS may be simultaneously patterned (or formed) when the respective components in the display area DA are patterned. For example, the dam member DS may have a structure in which the second bank BNK2 covers the insulating pattern INP and the first bank BNK1. However, embodiments are not limited thereto.

The dam member DS may be covered by the first capping layer CPL1. For example, the first capping layer CPL1 may be disposed on a side surface of the dam member DS that faces the outer portion of the display device DD (or the display panel DP). The dam member DS may be covered by the second capping layer CPL2. For example, the second capping layer CPL2 may be disposed on a side surface of the dam member DS that faces the outer portion of the display device DD.

A height of the dam member DS may correspond to a height of the second bank BNK2 that is disposed in the display area DA. The height of the dam member DS and the height of the second bank BNK2 that is disposed in the display area DA may be substantially same as each other. For example, an upper portion of the the dam member DS may be formed by the second bank BNK2. For example, a distance between an upper surface of the base layer BSL and an uppermost surface of the dam member DS and a distance between the upper surface of the base layer BSL and an uppermost surface of the second bank BNK2 may be substantially same as each other.

In a plan view, the dam member DS may overlap an opening area 1000. For example, the color filter layer CFL may not overlap at least a portion of a surface of the dam member DS, e.g., in a plan view.

The optical layer OPL may be disposed on the first capping layer CPL1. At least a portion of the optical layer OPL may be disposed adjacent to the dam member DS (e.g., in the first direction DR1 perpendicular to the third direction DR3). In an embodiment, the optical layer OPL may be inserted into and disposed in the area by which the first passivation layer PSV1 and the second passivation layer PSV2 are spaced apart from each other. For example, the optical layer OPL may be disposed between the first passivation layer PSV1 and the second passivation layer PSV2 in the first direction DR1 (or in a horizontal direction).

The second capping layer CPL2 may be disposed on the optical layer OPL. The second capping layer CPL2 may be disposed over the display area DA and the non-display area NDA.

In an embodiment, at least a portion of the second capping layer CPL2 may cover a side surface of the second passivation layer PSV2. At least a portion of the second capping layer CPL2 may cover a side surface of the dam member DS. In an embodiment, the second capping layer CPL2 may contact (e.g., directly contact) the cover layer 100 in the opening area 1000.

The planarization layer PLL may be disposed on the second capping layer CPL2, and may be disposed over the display area DA and the non-display area NDA. In an embodiment, a portion of the planarization layer PLL may be disposed between the dam member DS and the display area DA. Another portion of the planarization layer PLL may be disposed adjacent to a side of the dam member DS that faces the outer portion of the display device DD (or the display panel DP).

The color filter layer CFL may be disposed on the planarization layer PLL. The color filter layer CFL may be disposed over the display area DA and the non-display area NDA.

In an embodiment, as described above, each of the first to third color filters CF1, CF2, and CF3 may selectively pass a color of light therethrough in the display area DA. The first to third color filters CF1, CF2, and CF3 may be stacked, thus forming the light shielding layer CS.

The color filter layer CFL may further include an outer color filter layer OCF. The outer color filter layer OCF may include some of the first to third color filters CF1, CF2, and CF3 that are disposed in the non-display area NDA, among the first to third color filters CF1, CF2, and CF3 disposed to form the color filter layer CFL. For example, in an embodiment, the outer color filter layer OCF may include first color filters CF1′ disposed in the non-display area NDA, and third color filters CF3′ disposed in the non-display area NDA. For convenience of description, FIG. 8 illustrates an embodiment in which the outer color filter layer OCF does not include the second color filter CF2. For example, although all of the first to third color filters CF1, CF2, and CF3 may be stacked to form the light shielding layer CS for blocking light, at least one of the first to third color filters CF1, CF2, and CF3 may be omitted in the non-display area NDA. However, embodiments are not limited thereto.

The outer color filter layer OCF may be disposed in the non-display area NDA. The outer color filter layer OCF may overlap the dam member DS in the non-display area NDA, in a plan view. The outer color filter layer OCF may overlap the non-display area NDA, in a plan view. The outer color filter layer OCF may overlap the second passivation layer PSV2, in a plan view.

A portion of the outer color filter layer OCF may be disposed on the dam member DS. For example, the portion of the outer color filter layer OCF disposed on the dam member DS may have a shape corresponding to a surface of the dam member DS. For example, the dam member DS may extend to surround the display area DA (see FIG. 3). For example, the outer color filter layer OCF may extend along a side of the dam member (see FIG. 3).

For example, the outer color filter layer OCF may be disposed around a corner portion (or the upper portion) of the dam member DS. For example, the upper portion of the dam member DS may be adjacent to the outer color filter layer OCF in the first direction DR1.

The outer color filter layer OCF may expose at least a portion of the dam member DS. For example, the outer color filter layer OCF may not overlap at least a portion of a surface of the dam member DS, e.g., in a plan view. The outer color filter layer OCF may include a first outer color filter layer OCF1 and a second outer color filter layer OCF2. For example, the first outer color filter layer OCF1 may be formed to cover a side surface of the dam member DS. The second outer color filter layer OCF2 may be formed to cover another side surface of the dam member DS.

In an embodiment, the first outer color filter layer OCF1 may be disposed on a side (e.g., a left side) of the dam member DS, and may be disposed in a side (e.g., a left side) of the dam member DS that faces the outer portion of the display device DD (or the display panel DP). For example, the first outer color filter layer OCF1 may include a first color filter CF1′ and a third color filter CF3′ which are disposed on a surface (e.g., a left side) of the dam member DS that is oriented in an outer direction. In an embodiment, the second outer color filter layer OCF2 may be disposed on another side (e.g., a right side) of the dam member DS, and may be disposed in another side (e.g., a right side) of the dam member DS that faces the inside of the display device DD. For example, the second outer color filter layer OCF2 may include a first color filter CF1′ and a third color filter CF3′ that are disposed on another surface of the dam member DS that faces the display area DA. For instance, the second outer color filter layer OCF2 may be connected to the first to third color filters CF1, CF2, and CF3 that are disposed in the display area DA.

The first outer color filter layer OCF1 and the second outer color filter layer OCF2 may be spaced apart from each other by the opening area 1000 interposed therebetween. The first outer color filter layer OCF1 and the second outer color filter layer OCF2 may be spaced apart from each other so that the opening area 1000 may be defined therebetween. In an embodiment, the first outer color filter layer OCF1 and the second outer color filter layer OCF2 may be separated (e.g., physically separated) from each other. For example, the first outer color filter layer OCF1 and the second outer color filter layer OCF2 may be separated from each other on a surface of the dam member DS.

In an embodiment, in the non-display area NDA, the first outer color filter layer OCF1 and the second outer color filter layer OCF2 may be spaced apart from each other, so that an external influence on the components of the display device DD may be substantially reduced. For example, the first outer color filter layer OCF1 and the second outer color filter layer OCF2 may be separated from each other on an upper surface of the dam member DS, so that the foregoing effect may be further increased. For example, the dam member DS may have a protruded shape. For example, a thickness of the color filter layer CFL patterned on the dam member DS may be less than a thickness of the other areas. In an embodiment, the opening area 1000, by which the first outer color filter layer OCF1 and the second outer color filter layer OCF2 are spaced apart from each other, may be defined in the area where the thickness of the color filter layer CFL may be relatively reduced. For example, in the opening area 1000, two or more inorganic layers (e.g., the second capping layer CPL2 and the cover layer 100) may contact each other, thus preventing permeation of external moisture. In other words, according to the above-mentioned structure, the opening area 1000 may be more readily fabricated, so that an external influence on the display device DD may be further reduced.

The first outer color filter layer OCF1 and the second outer color filter layer OCF2 may be spaced apart from each other so that the components that are patterned (or formed) before the color filter layer CFL is patterned (or formed) may be exposed. For example, the first outer color filter layer OCF1 and the second outer color filter layer OCF2 may be spaced apart from each other, so that the second capping layer CPL2 may be exposed. Hence, in the opening area 1000 defined by the first outer color filter layer OCF1 and the second outer color filter layer OCF2, the second capping layer CPL2 and the cover layer 100 may contact (e.g., directly contact) each other.

The cover layer 100 may be disposed on the color filter layer CFL. The cover layer 100 may be disposed over the display area DA and the non-display area NDA.

The cover layer 100 may cover the color filter layer CFL and protect the color filter layer CFL. In an embodiment, the cover layer 100 may cover a side surface of the optical layer OPL. The cover layer 100 may cover the first outer color filter layer OCF1.

The cover layer 100 may contact (e.g., directly contact) the second capping layer CPL2 in the opening area 1000. For example, the cover layer 100 may be inserted into the opening area 1000 formed by the first outer color filter layer OCF1 and the second outer color filter layer OCF2. For example, the cover layer 100 disposed in the opening area 1000 may be disposed between the first outer color filter layer OCF1 and the second outer color filter layer OCF2 in the first direction DR1.

In an embodiment, the cover layer 100 may cover the components of the color filter layer CFL, and therefore protect the color filter layer CFL from an external influence. For example, the cover layer 100 may cover the entirety of a surface (e.g., the first outer color filter layer OCF1) of the color filter layer CFL that faces the outer portion of the display device DD (or the display panel DP). For example, external factors such as moisture may be substantially prevented from being penetrated into the display device DD (or the display panel DP).

For example, in an embodiment, after components (e.g., the light emitting element LD, the color conversion layer CCL, and the like) are successively formed on the base layer BSL, the color filter layer CFL may be formed on the components, rather than being formed on a separate fabrication substrate. For example, the base layer BSL having a substrate structure may be formed on a surface (e.g., a lower surface) of the display device DD in accordance with an embodiment, and an outer film layer OFL having a film member may be formed on another surface (e.g., an upper surface) of the display device DD.

The overcoat layer OC may be disposed on the color filter layer CFL, and may be disposed over the display area DA and the non-display area NDA. As described above, the overcoat layer OC may offset (or compensate) a step difference formed by disposing individual components.

Although not shown in FIG. 8, the outer film layer OFL may be disposed on the overcoat layer OC. As described above, the color filter layer CFL may be formed on the base layer BSL as a mother substrate. Hence, the outer film layer OFL including a film member, rather than a fabrication substrate, may be disposed in the outer portion of the display device DD.

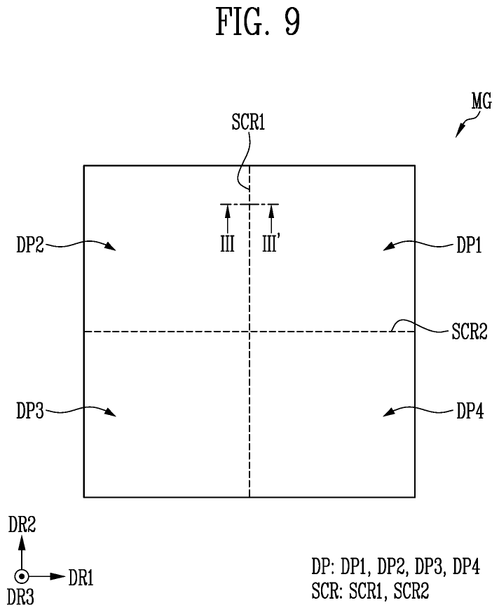

Hereinafter, a method of fabricating the display device DD in accordance with an embodiment will be described with reference to FIGS. 9 to 18. Redundant descriptions will be simplified, or may not be repeated to avoid redundancy.

FIGS. 9 to 18 are schematic views illustrating, by process steps, a method of fabricating the display device DD in accordance with an embodiment.

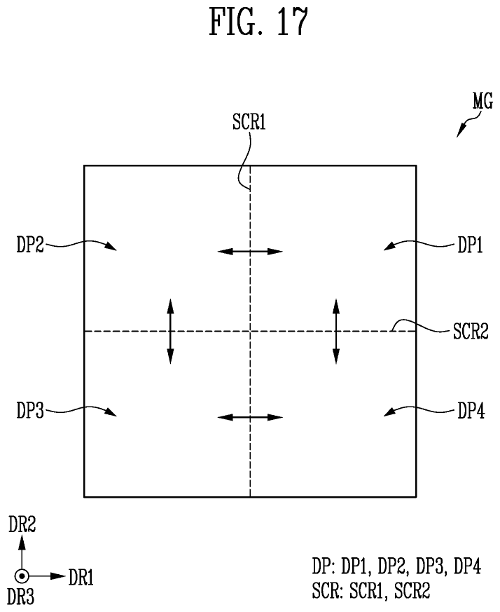

FIGS. 9 and 17 are schematic plan views illustrating, by process steps, the method of fabricating the display device DD in accordance with an embodiment. FIGS. 9 and 17 are schematic plan views illustrating a mother substrate MG in accordance with an embodiment.

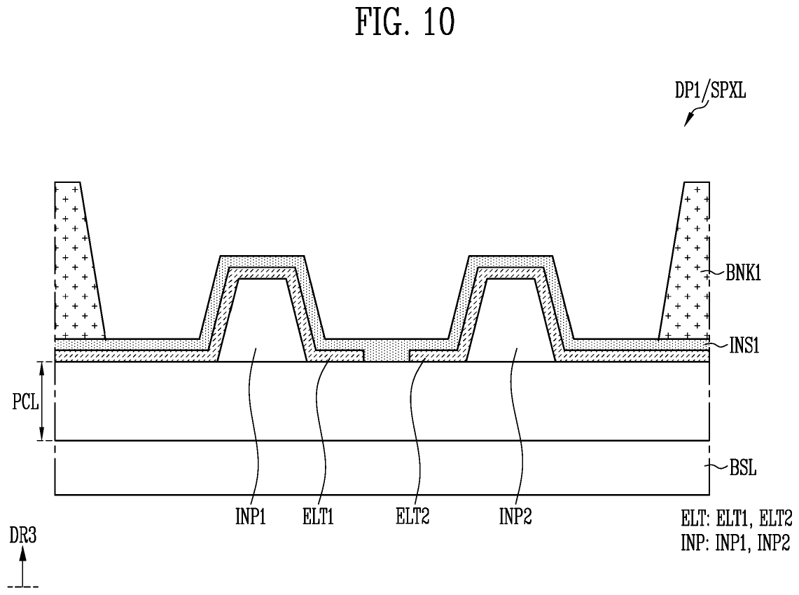

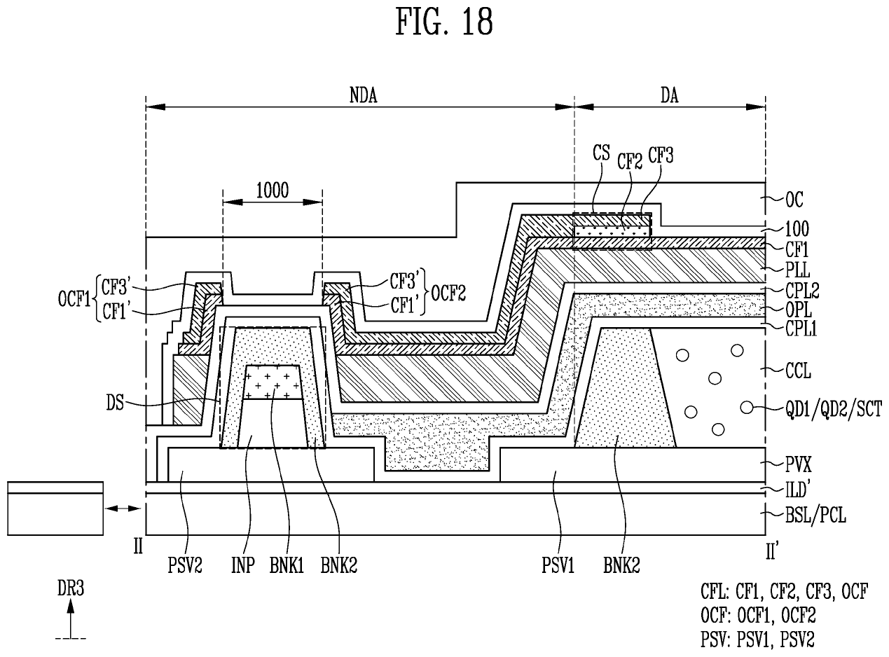

FIGS. 10 to 16 and 18 are schematic sectional views illustrating, by process steps, the method of fabricating the display device DD in accordance with an embodiment. FIGS. 10 to 16 are schematic sectional views taken along line III-III′ of FIG. 9. FIG. 18 illustrates a sectional structure taken along line II-II′ of FIG. 3 described above.

FIGS. 10 to 13 are schematic sectional views schematically illustrating a method of fabricating the display device DD with regard to a sectional structure in the display area DA. For example, FIGS. 10 to 13 illustrate a sectional structure of FIG. 7 described above.

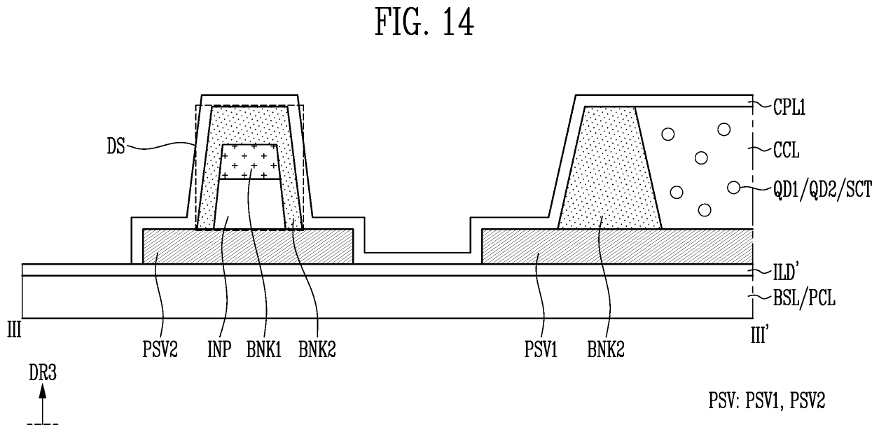

FIGS. 14 to 16 and 18 are schematic sectional views schematically illustrating a method of fabricating the display device DD with regard to a sectional structure of an area adjacent to the non-display area NDA. For example, FIGS. 14 to 16 and 18 illustrate sectional structures including a sectional structure of FIG. 8 described above.

In an embodiment, FIGS. 9 to 16 are schematic views before a process of cutting the mother substrate MG is performed. In an embodiment, FIGS. 17 and 18 are schematic views after the process of cutting the mother substrate MG is performed.

First, processes of the method of fabricating the display device DD before the process of cutting the mother substrate MG is performed will be described with reference to FIGS. 9 to 16.

Referring to FIGS. 9 to 16, the mother substrate MG may be manufactured to fabricate the display device DD in accordance with an embodiment. In an embodiment, the mother substrate MG may be provided to simultaneously fabricate display panels DP on a single large substrate. The mother substrate MG may include a base layer BSL which forms a base surface, and electrodes, organic layers, and inorganic layers which are disposed on the base layer BSL. After the mother substrate MG has been manufactured, the display panels DP may be separated from each other by performing a cutting process (e.g., a scribing process). For example, the mother substrate MG may include display panels DP which are divided from each other by a first scribing line SCR1 extending in the second direction DR2 and a second scribing line SCR2 extending in the first direction DR1.

In an embodiment, FIG. 9 illustrates the mother substrate MG for manufacturing the first to fourth display panels DP1 to DP4. After the mother substrate MG for manufacturing the first to fourth display panels DP1 to DP4 may be manufactured, the first to fourth display panels DP1 to DP4 may be individually divided from each other, thus being defined as individual display panels DP.

Hereinafter, processes to be performed on the respective display panels DP to manufacture the mother substrate MG will be described with reference to FIGS. 10 to 16. For convenience of description, the following description will be made, based on the first display panel DP1 among the display panels DP of the mother substrate MG. For example, FIGS. 10 to 13 illustrate process steps on an area of a sub-pixel SPXL of the first display panel DP1. FIGS. 14 to 16 illustrate the process steps on a peripheral area of the first display panel DP1.

First, description of the process steps on an area in which the sub-pixel SPXL of the first display panel DP1 is formed will be made.

Referring to FIG. 10, the pixel circuit layer PCL may be disposed on the base layer BSL, and insulating patterns INP and alignment electrodes ELT may be disposed (or patterned). The first insulating layer INS1 may be disposed (or patterned) on the alignment electrodes ELT. The first bank BNK1 may be disposed (or patterned) on the first insulating layer INS1.

In the step, layers of the pixel circuit layer PCL disposed on the base layer BSL, electrode layers (e.g., the alignment electrodes ELT), and insulating layers (e.g., the first insulating layer INS1) may be formed by patterning a conductive layer (or a metal layer), an inorganic layer, an organic layer, or the like by a photolithography process using a mask.

In the step, the first electrode ELT1 and the second electrode ELT2 may be patterned by depositing a base electrode on the pixel circuit layer PCL and etching at least a portion of the base electrode.

In the step, the first electrode ELT1 and the second electrode ELT2 may be formed to respectively cover the first insulating pattern INP1 and the second insulating pattern INP2. Therefore, in the step, at least a portion of each of the first electrode ELT1 and the second electrode ELT2 may function as a reflective wall.

In an embodiment, the first bank BNK1 may define (or form) space in which fluid may be received. For example, in FIG. 10, the first bank BNK1 that is disposed on a side and the first bank BNK1 that is disposed on the other side may be formed such that fluid may be received therebetween.

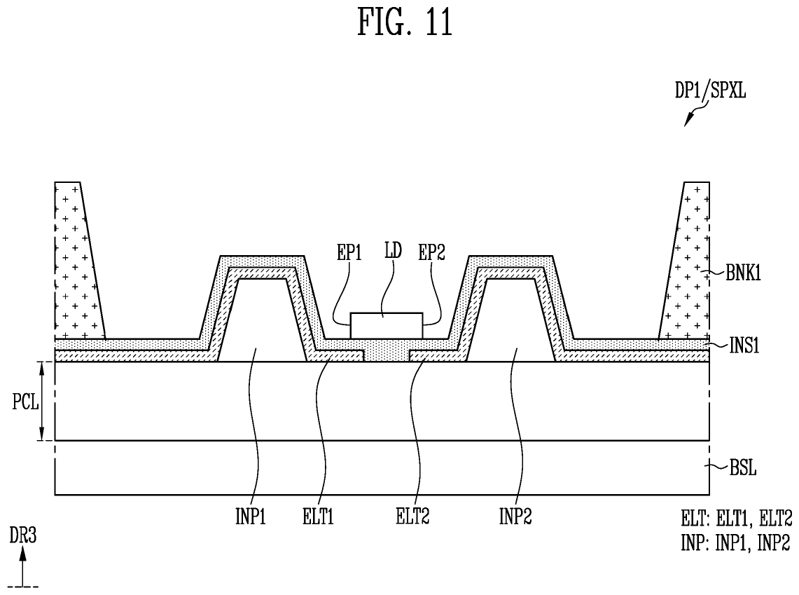

Referring to FIG. 11, the light emitting element LD may be disposed on the base layer BSL (e.g., the first insulating layer INS1). The light emitting elements LD may be aligned between the first electrode ELT1 and the second electrode ELT2.

In an embodiment, ink including the light emitting element LD may be supplied onto the base layer BSL (e.g., the first insulating layer INS1). The ink may be provided by a printing device capable of spraying fluid. For example, the printing device may include a nozzle device that discharges liquefied fluid to the outside. The ink may include a solvent and the light emitting element LD. Light emitting elements LD may be provided and dispersed in the solvent having fluidity. In an embodiment, the solvent may include an organic solvent. For example, the solvent may be one of propylene glycol methyl ether acetate (PGMEA), dipropylen glycol n-propyl ether (DGPE), and triethylene gylcol n-butyl ether (TGBE). However, embodiments are not limited thereto, and the solvent may include various organic solvents.

The ink including the light emitting elements LD may be received in the space formed by the first bank BNK1. Thereafter, an electric field may be formed between the first electrode ELT1 and the second electrode ELT2, so that the light emitting elements LD may be aligned based on the electric field. For example, a first alignment signal may be provided to the first electrode ELT1, and a second alignment signal may be provided to the second electrode ELT2. An electric field based on the first alignment signal and the second alignment signal may be generated (or formed) in an area in which the light emitting elements LD are to be aligned. In an embodiment, electrical signals (e.g., alignment signals) to be provided to the alignment electrodes ELT may include an AC signal. For example, the first alignment signal may be an AC signal, and the second alignment signal may be a ground signal. However, embodiments are not limited thereto. The AC signal may have any one waveform of a sine waveform, a triangular waveform, a step wave, a trapezoidal waveform, and a pulse waveform, but embodiments are not limited thereto. The AC signal may have various AC signal forms.

In an embodiment, the light emitting elements LD may be moved (or rotated) by force (e.g., dielectrophoresis (DEP) force) generated based on the electric field, and thus be aligned (or disposed) on the first insulating layer INS1. For example, the moved light emitting elements LD may be aligned on the alignment electrodes ELT.

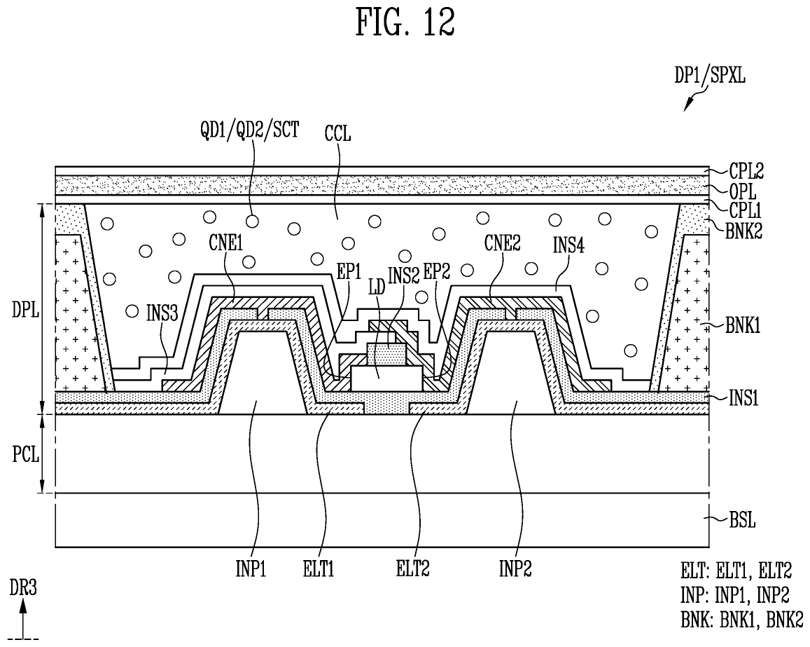

Referring to FIG. 12, the second insulating layer INS2 may be formed on the light emitting elements LD. The first contact electrode CNE1 may be patterned and connected (e.g., electrically connected) to the first end portion EP1 of the light emitting element LD. The third insulating layer INS3 may be patterned on the first contact electrode CNE1. The second contact electrode CNE2 may be patterned and connected (e.g., electrically connected) to the second end portion EP2 of the light emitting element LD. The fourth insulating layer INS4 may be patterned on the third insulating layer INS3 and the second contact electrode CNE2. The second bank BNK2 may be disposed (or patterned) and overlap the first bank BNK1.

FIG. 12 illustrates an embodiment in which the first contact electrode CNE1 and the second contact electrode CNE2 are patterned by different processes. However, embodiments are not limited thereto. In some embodiments, the first contact electrode CNE1 and the second contact electrode CNE2 may be formed by a same process.

In an embodiment, the second bank BNK2 may define (or form) space in which the color conversion layer CCL is received. For example, referring to FIG. 12, the color conversion layer CCL may be disposed in the space between the opposite sides (e.g., left and right sides) of the second bank BNK2.

In the step, the color conversion layer CCL including at least one selected from the group consisting of the first quantum dot QD1, the second quantum dot QD2, and the light scatterer SCT may be formed (or patterned) in the space formed by the second bank BNK2.

Thereafter, the first capping layer CPL1 for sealing (or encapsulating) the color conversion layer CCL may be disposed (or formed), and the optical layer OPL and the second capping layer CPL2 may be successively disposed (or formed).

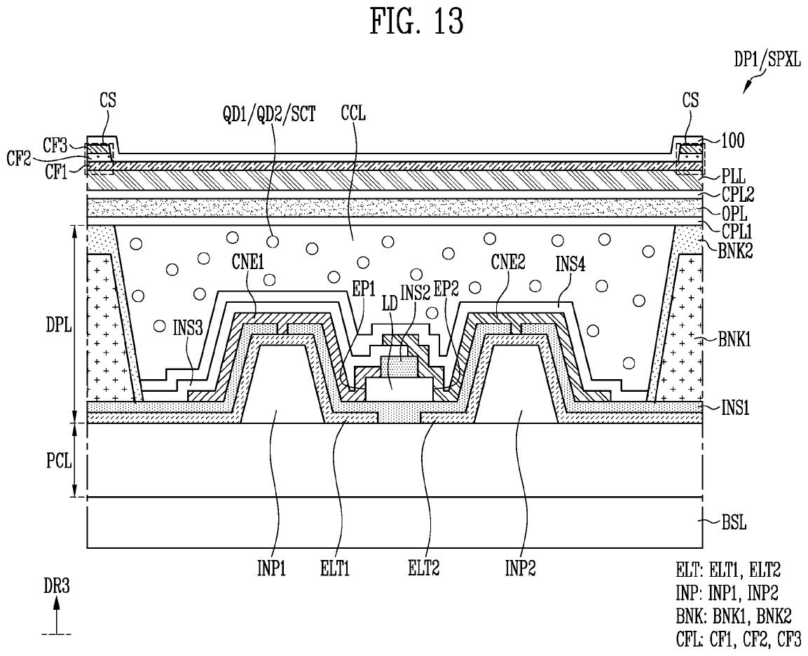

Referring to FIG. 13, the planarization layer PLL may be disposed (or formed) on the second capping layer CPL2. The color filter layer CFL may be disposed (or patterned) on the planarization layer PLL. For convenience of description, FIG. 13 illustrates an embodiment in which the sub-pixel SPXL is a first sub-pixel SPXL1 that emits a first color of light. For example, only the first color filter CF1 may be disposed in an area from which light of the light emitting element LD is emitted.

In an embodiment, after having been patterned on a separate fabrication substrate, the color filter layer CFL may not be coupled to a panel on which the light emitting element LD and the color conversion layer CCL are formed. For example, the color filter layer CFL in accordance with an embodiment may be formed on the base layer BSL which is a base surface for forming the light emitting element LD and the color conversion layer CCL.

In the step, the first to third color filters CF1, CF2, and CF3 may be patterned to pattern the color filter layer CFL. For example, FIG. 13 illustrates an embodiment in which the first to third color filters CF1, CF2, and CF3 are successively formed. However, embodiments are not limited thereto, and an arrangement sequence of the first to third color filters CF1, CF2, and CF3 may be appropriately changed.

In the step, the light shielding layer CS may be formed at a position at which the first to third color filters CF1, CF2, and CF3 overlap each other, in a plan view. For example, the light shielding layer CS may be formed between adjacent sub-pixels SPXL so that the adjacent sub-pixels SPXL may be separated from each other.

In the step, the cover layer 100 may be disposed (or formed) on the color filter layer CFL. For example, the cover layer 100 may cover the entirety of a surface of the color filter layer CFL. In an embodiment, the cover layer 100 may cover an outermost surface of the color filter layer CFL (e.g., an outermost surface of the third color filter CF3). Hence, although the process of successively forming the color filter layer CFL on the base layer BSL is performed, the color filter layer CFL may be substantially prevented from being damaged by an external influence.

The cover layer 100 may also cover the color filter layer CFL that is disposed on the perimeter of the first display panel DP1, so that the inside of the first display panel DP1 may be prevented from being affected by an external factor (e.g., moisture or the like). Detailed description pertaining thereto will be made below herein.

Thereafter, the overcoat layer OC may be formed on the cover layer 100, and the outer film layer OFL may be formed on the overcoat layer OC.

A process step on the peripheral area of the first display panel DP1 will be described with reference to FIGS. 14 to 16. For convenience of description, the process step on the peripheral area of the first display panel DP1 will be described separately from the process step on the area where the above-mentioned sub-pixel SPXL is disposed. For example, components specified by a same reference numerals in the above-mentioned contents may be formed (or patterned) at a same time point (or during a same process). Redundant descriptions will be simplified, or may not be repeated to avoid redundancy.

Referring to FIG. 14 along with FIGS. 10 to 12, the interlayer insulating layer ILD′ may be disposed (or formed) on the base layer BSL. The first passivation layer PSV1 and the second passivation layer PSV2 may be disposed (or formed) on the interlayer insulating layer ILD′.

In the step, the first passivation layer PSV1 and the second passivation layer PSV2 may be patterned at positions spaced apart from each other. For example, the second passivation layer PSV2 may form an area where the dam member DS may be disposed, and may be separated (e.g., physically separated) from the first passivation layer PSV1 which forms an area where the color conversion layer CCL is disposed. For example, external impurities may be further reliably prevented from permeating the first passivation layer PSV1 disposed in the display area DA through the second passivation layer PSV2 adjacent to the peripheral area.

In the step, the second bank BNK2 and the color conversion layer CCL may be patterned on the first passivation layer PSV1. The dam member DS may be patterned on the second passivation layer PSV2. The first capping layer CPL1 may be formed to cover the dam member DS and seal (or encapsulate) the color conversion layer CCL.

In an embodiment, the dam member DS may have a structure including the insulating pattern INP, the first bank BNK1, and the second bank BNK2. Therefore, the dam member DS may be formed by successively stacking the insulating pattern INP, the first bank BNK1, and the second bank BNK2.

In the step, the first capping layer CPL1 may cover an outer surface of the second passivation layer PSV2. For example, the first capping layer CPL1 may cover a side surface of the second passivation layer PSV2 that faces the outer portion. The first capping layer CPL1 may contact (e.g., directly contact) the interlayer insulating layer ILD′. For example, the first passivation layer PSV1 and the second passivation layer PSV2 may be spaced apart from each other so that a portion of the interlayer insulating layer ILD′ may be exposed. In cas that the first capping layer CPL1 is formed, the exposed portion of the interlayer insulating layer ILD′ may contact (e.g., directly contact) the first capping layer CPL1.

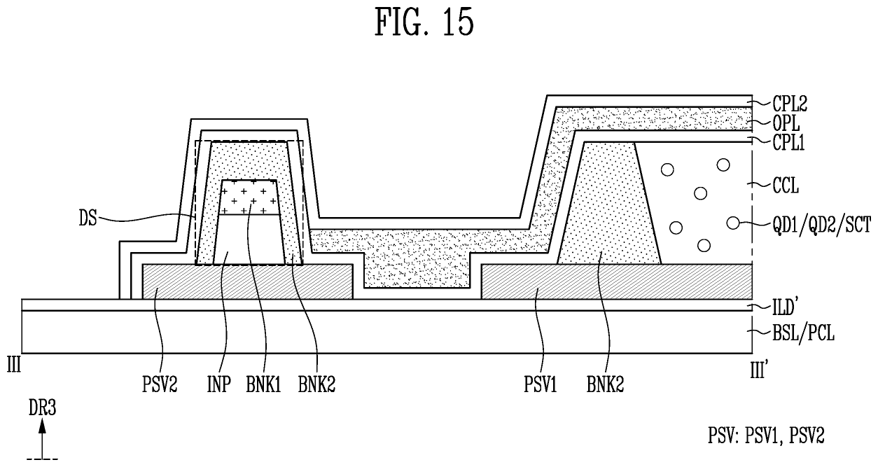

Referring to FIG. 15 along with FIG. 12, the optical layer OPL may be disposed on the first capping layer CPL1, and the second capping layer CPL2 may be formed on the optical layer OPL.

In the step, the second capping layer CPL2 may cover the dam member DS and the second passivation layer PSV2. For example, the second capping layer CPL2 may be disposed on a side surface of the second passivation layer PSV2 and a side surface of the dam member DS that face the outer portion, with the first capping layer CPL1 interposed between the second capping layer CPL2 and the side surfaces of the second passivation layer PSV2 and the dam member DS.

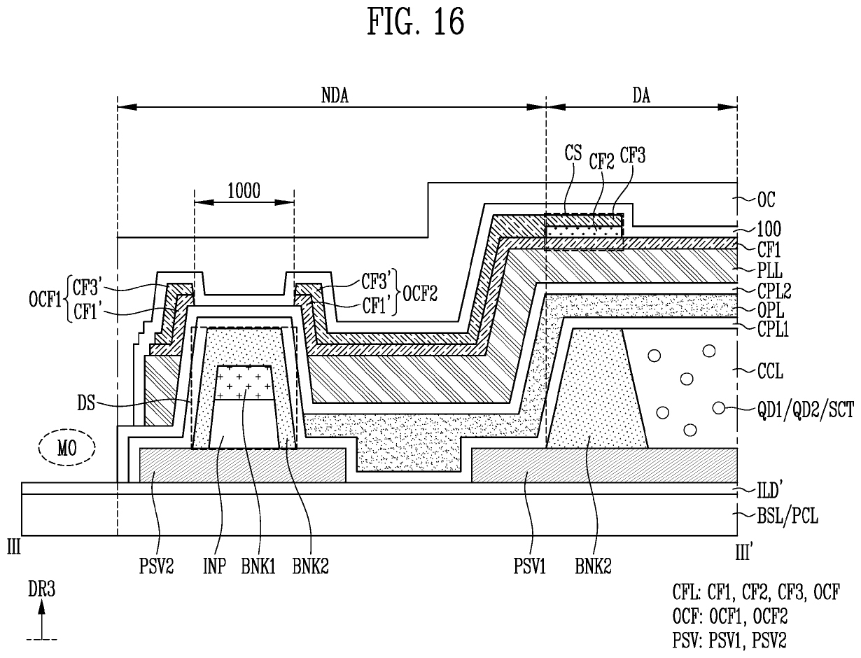

Referring to FIG. 16 along with FIG. 13, the planarization layer PLL may be disposed on the second capping layer CPL2, and the color filter layer CFL may be disposed on the planarization layer PLL. In an embodiment, at least portions of the color filter layer CFL may be separated from each other in the non-display area NDA.

In the step, the outer color filter layer OCF may be disposed in the non-display area NDA. For example, the outer color filter layer OCF may not be disposed on at least a portion of a surface of the dam member DS. For example, after the color filter layer CFL is formed on the overall surfaces of the display area DA and the non-display area NDA., at least a portion of the color filter layer CFL may be removed. For example, at least a portion of the color filter layer CFL that is disposed on the dam member DS may be removed, so that the first outer color filter layer OCF1 and the second outer color filter layer OCF2 may be separated from each other on the upper surface of the dam member DS. Hence, the opening area 1000 may be formed in the upper surface of the dam member DS. The second capping layer CPL2 that is disposed on the upper surface of the dam member DS may be exposed. For example, the second capping layer CPL2 may contact (e.g., directly contact) the cover layer 100. For example, there may be formed a structure in which two layers including an inorganic material contact each other on the upper surface of the dam member DS. For example, moisture MO may be substantially prevented from permeating the display area DA.

In the step, the cover layer 100 may be disposed on the color filter layer CFL. The cover layer 100 may cover the first outer color filter layer OCF1, the second outer color filter layer OCF2, the second capping layer CPL2 disposed on the dam member DS, and the color filter layer CFL disposed in the display area DA. In an embodiment, the cover layer 100 may cover a side surface of the planarization layer PLL that is adjacent to the outer portion and is disposed under the first outer color filter layer OCF1.

In an embodiment, the cover layer 100 may cover side surfaces of components that are disposed in the outer portion of the first display panel DP1. For example, the cover layer 100 may cover a side surface of the first outer color filter layer OCF1 facing the outer portion of the first display panel DP1. Hence, the cover layer 100 may effectively protect the first display panel DP1 from external impurities (e.g., moisture MO).

Thereafter, the overcoat layer OC may be disposed on the cover layer 100. For example, the outer film layer OFL may be disposed on the overcoat layer OC. Hence, components disposed to form the display panel DP may be successively formed, whereby the mother substrate MG may be manufactured.

Processes of the method of fabricating the display device DD including the process of cutting the mother substrate MG will be described with reference to FIGS. 17 and 18. Redundant descriptions will be simplified, or may not be repeated to avoid redundancy.

As described above, the manufactured mother substrate MG may be cut by a cutting process, and thus divided into a plurality of display panels DP. For example, referring to FIGS. 17 and 18, the mother substrate MG may be cut based on the first scribing line SCR1 and the second scribing line SCR2, so that the first to fourth display panels DP1, DP2, DP3, and DP4 may be provided. For example, a polishing process may be performed on peripheral surfaces of the display panels DP.

In an embodiment, the scribing line SCR along which the cutting process is performed may be defined in an area other than the second passivation layer PSV2 disposed in an outer portion of each display panel DP. For example, referring to FIG. 18, the line along which the cutting process is performed may not overlap the position of the second passivation layer PSV2. For example, at least a portion of the second passivation layer PSV2 may not cut, and the second passivation layer PSV2 may not be exposed. In other words, in an embodiment, although the cutting process is performed, the second passivation layer PSV2 may still be covered by the layers (e.g., the first capping layer CPL1) including an inorganic material. For example, external impurities including moisture MO may be substantially prevented from permeating the display panel DP.

Various embodiments of the disclosure may provide a display device capable of being protected from an external influence, and a method of fabricating the display device.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device including a display area and a non-display area, the display device comprising:
a light emitting element on a base layer in the display area;
a dam member on the base layer in the non-display area;
a color filter layer disposed in the display area and the non-display area, the color filter layer including an outer color filter layer disposed in the non-display area; and
a cover layer on the color filter layer, wherein
the cover layer covers at least a portion of the outer color filter layer.

2. The display device according to claim 1, further comprising:
a passivation layer on the base layer, the passivation layer including:
a first passivation layer in the display area, and
a second passivation layer in the non-display area;
a bank on the first passivation layer; and
a color conversion layer in an area surrounded by the bank, wherein
the dam member is on the second passivation layer, and
at least a portion of the dam member and the bank include a same material.

3. The display device according to claim 2, further comprising a capping layer, wherein
at least a portion of the capping layer encapsulates the color conversion layer,
the capping layer covers a side surface of the dam member facing an outer portion of the display device.

4. The display device according to claim 2, wherein a height of the dam member and a height of the bank are substantially same as each other.

5. The display device according to claim 3, wherein
the passivation layer includes an organic material, and
the capping layer covers a side surface of the second passivation layer facing the outer portion of the display device.

6. The display device according to claim 2, further comprising:
a capping layer encapsulating the color conversion layer; and
an interlayer insulating layer disposed between the passivation layer and the base layer, wherein
the first passivation layer and the second passivation layer are spaced apart from each other, and
the capping layer and the interlayer insulating layer contact each other in an area where the first passivation layer and the second passivation layer are spaced apart from each other.

7. The display device according to claim 1, wherein the cover layer covers an outer surface of the outer color filter layer facing an outer portion of the display device.

8. The display device according to claim 1, wherein
the outer color filter layer comprises a first outer color filter layer and a second outer color filter layer, and
the first outer color filter layer and the second outer color filter layer are spaced apart from each other on an upper surface of the dam member.

9. The display device according to claim 8, further comprising a capping layer, at least a portion of the capping layer being disposed on the dam member, wherein
the first outer color filter layer and the second outer color filter layer are separated from each other to form an opening area overlapping the dam member in a plan view, and
the cover layer and the capping layer contact each other in the opening area.

10. The display device according to claim 1, wherein the outer color filter layer extends along a side of the dam member.

11. The display device according to claim 1, wherein
the base layer including a substrate is formed on a surface of the display device, and
an outer film layer including a film member is formed on another surface of the display device.

12. The display device according to claim 1, wherein the light emitting element comprises an organic light emitting diode including an organic material or a subminiature light emitting diode including an inorganic material.

13. A display device including a display area and a non-display area, the display device comprising:
a light emitting element on a base layer in the display area;
a dam member on the base layer in the non-display area; and
a color filter layer disposed in the display area and the non-display area, the color filter layer including an outer color filter layer disposed in the non-display area, wherein
the outer color filter layer comprises a first outer color filter layer and a second outer color filter layer that are spaced apart from each other on an upper surface of the dam member.

14. A method of fabricating a display device, the method comprising:
disposing a pixel circuit layer and a light emitting element on a base layer of a mother substrate;
forming a dam member on the base layer;
forming a color filter layer on the base layer, the forming of the color filter layer including:
forming at least a portion of the color filter layer to overlap an area in which the light emitting element is disposed, and
forming an outer color filter layer on a first side surface of the dam member; and
disposing a cover layer on the color filter layer, wherein
the cover layer covers at least a portion of the outer color filter layer.

15. The method according to claim 14, further comprising cutting the mother substrate along a scribing line to form a plurality of display panels, wherein
the disposing of the pixel circuit layer comprises disposing a passivation layer on the base layer, and
the scribing line and the passivation layer do not overlap each other.

16. The method according to claim 14, further comprising disposing alignment electrodes on the base layer, wherein
the disposing of the light emitting element comprises:
supplying ink including the light emitting element and a solvent onto the base layer;
generating an electric field by providing electrical signals to the alignment electrodes; and
aligning the light emitting element based on the electric field.

17. The method according to claim 14, wherein the cover layer covers an outer surface of the outer color filter layer facing an outer portion of the display device.

18. The method according to claim 14, wherein the cover layer covers an outer surface of the outer color filter layer facing an outer portion of the display device.

19. The method according to claim 14, wherein
the forming of the outer color filter layer comprises:
forming a first outer color filter layer for covering the first side surface of the dam member; and
forming a second outer color filter layer for covering a second side surface of the dam member, and
the first outer color filter layer and the second outer color filter layer are spaced apart from each other on an upper surface of the dam member.

20. The method according to claim 19, wherein the cover layer contacts a capping layer disposed on a surface of the dam member in an area by which the first outer color filter layer and the second outer color filter layer are spaced apart from each other.
